(19) United States
(12) Patent Application Publication
(10) Pub. No.: US 2011/0168330 A1
(43) Pub. Date: Jul. 14, 2011

(54) SUPPORT STRUCTURE, LOAD LOCK APPARATUS, PROCESSING APPARATUS AND TRANSFER MECHANISM

(75) Inventors: Hiromitsu SAKAUE, Nirasaki City (JP); Takashi HORIUCHI, Nirasaki City (JP); Kaoru FUJIHARA, Nirasaki City (JP)

(73) Assignee: TOKYO ELECTRON LIMITED, Tokyo (JP)

(21) Appl. No.: 13/006,787

(22) Filed: Jan. 14, 2011

(30) Foreign Application Priority Data
Jan. 14, 2010 (JP) 2010-006030
Jul. 13, 2010 (JP) 2010-159193

(51) Int. Cl. H01L 21/3065; C23C 16/50; B05C 13/02

(52) U.S. Cl. 156/345.31; 118/723 VE; 118/500; 156/345.51; 156/345.55

(57) ABSTRACT

A support structure for supporting a processing target object includes a support main body that supports a weight of the processing target object and recess-shaped supporting body accommodating portions formed on a top surface of the support main body. The support structure further includes supporting bodies accommodated in the respective supporting body accommodating portions to be protruded above the top surface of the support main body. The supporting bodies are rollable in the respective supporting body accommodating portions while supporting the processing target object of which bottom surface is in contact with upper peak portions of the supporting bodies.

### CROSS-REFERENCE TO RELATED APPLICATIONS

This application claims priority to Japanese Patent Application Nos. 2010-006030 filed on Jan. 14, 2010; and 2010-159193 filed on Jul. 13, 2010, the entire contents of which are incorporated herein by reference.

### FIELD OF THE INVENTION

The present invention relates to a support structure for supporting a processing target object such as a semiconductor wafer, a load lock apparatus using the support structure, a processing apparatus and a transfer mechanism.

### BACKGROUND OF THE INVENTION

In general, in order to manufacture a semiconductor device or the like, various processes such as a film forming process, an etching process, an oxidation/diffusion process and a quality modification process need to be performed on a disc-shaped processing target object such as a semiconductor wafer or a glass substrate. For example, when such processes are performed on a semiconductor wafer in a single-wafer type vacuum processing apparatus, a load lock apparatus having a small capacity and configured to be rapidly switchable between a vacuum atmosphere and an atmospheric pressure is provided at a front end side of the vacuum processing apparatus such that the semiconductor wafer can be loaded into or unloaded from the vacuum processing apparatus via the load lock apparatus while maintaining a vacuum atmosphere in the vacuum processing apparatus (see, e.g., Japanese Patent Application Publication No. 2007-260624).

After the various processes are performed on the semiconductor wafer in the vacuum processing apparatus, a temperature of the semiconductor wafer may rise to a high level ranging, e.g., from about 300° C. to about 700° C. When the load lock apparatus is provided to unload therethrough the semiconductor wafer in such a high temperature state from the vacuum processing apparatus, the semiconductor wafer is rapidly cooled down to a safe temperature of, e.g., about 100° C. or thereabout in the load lock apparatus to improve throughput without suffering formation of a scratch or the like on the semiconductor wafer due to thermal contraction. Then, the cooled semiconductor wafer is unloaded to a rear end side of the load lock apparatus. Here, a configuration of a conventional load lock apparatus will be described. FIG. 31 is a schematic configuration view illustrating an example of the inside of the conventional load lock apparatus.

As illustrated in FIG. 31, a support structure 1 is provided in the load lock apparatus. The support structure 1 includes a support main body 2 that supports a weight of a semiconductor wafer W, and the support main body 2 is held on a supporting column 4. The semiconductor wafer W is mounted on the support main body 2 by being transferred by a plurality of, e.g., three elevating pins 5 that can be raised above and retracted below the support main body 2.

A cooling jacket 6 for cooling the semiconductor wafer W is provided within the support main body 2, and by allowing a coolant to flow in the cooling jacket 6, the semiconductor wafer W in the high temperature state can be cooled to a safe temperature. Further, a multiple number of, e.g., nine short supporting pins 8 are fixed on the support main body 2, and the semiconductor wafer W is supported on these supporting pins 8 while its rear surface is in contact with upper peaks of the supporting pins 8.

Further, a small gap equal to or less than about 1 mm is provided between the rear surface of the semiconductor wafer W and a planar top surface of the support main body 2 by supporting the rear surface (bottom surface) of the semiconductor wafer W on the supporting pins 8. This gap is provided to cool the semiconductor wafer W rapidly while avoiding sudden cooling, which may cause formation of a crack or the like in the semiconductor wafer W.

As described above, by supporting the semiconductor wafer W on the short supporting pins 8 provided on the top surface of the support main body 2, the temperature of the semiconductor wafer W can be rapidly lowered without causing formation of a crack or the like in the semiconductor wafer W.

As mentioned above, however, the semiconductor wafer W held on the support main body 2 may have a high temperature ranging from about 300° C. to about 700° C. depending on the kind of a process previously performed thereon. In such a case, the semiconductor wafer W may suffer a thermal contraction ranging from at least about 0.1 mm to about 0.4 mm in its size when it is cooled, though the amount of the thermal contraction may vary depending on the temperature or the size of the semiconductor wafer W. As a result, a scratch or a flaw may be generated on the rear surface of the semiconductor wafer due to friction between the rear surface of the semiconductor wafer W and the upper peaks of the supporting pins 8 in contact with the semiconductor wafer W. The scratch or flaw may cause particle generation. Further, in a subsequent process, such a scratch or flaw may become a core in forming an unnecessary thick film, and the unnecessary thick film may cause a focus deviation during an exposure process.

Further, as a technique related to a semiconductor device manufacturing apparatus, there is known a ball contact type semiconductor wafer chuck as described in Japanese Patent Application Publication No. S62-193139. In this ball contact type wafer chuck, a semiconductor wafer is fixed on a ball of a chuck main body by vacuum absorption and is transformed into a predetermined shape when necessary. However, this technique does not solve the above-mentioned problems.

### SUMMARY OF THE INVENTION

In view of the above, the present invention provides a support structure capable of supporting a processing target object such as a semiconductor wafer while preventing formation of a scratch or a flaw on a rear surface (bottom surface) of the processing target object. Further, the present invention also provides a load lock apparatus, a processing apparatus and a transfer mechanism.

In accordance with one aspect of the present invention, there is provided a support structure for supporting a processing target object, including: a support main body that supports a weight of the processing target object; recess-shaped supporting body accommodating portions formed on a top surface of the support main body; and supporting bodies accommodated in the respective supporting body accommodating portions to be protruded above the top surface of the support main body, the supporting bodies being rollable in the respective supporting body accommodating portions while supporting the processing target object of which bottom surface is in contact with upper peak portions of the supporting bodies.

In accordance with another aspect of the present invention, there is provided a support structure for supporting a processing target object, including: a support main body that supports a weight of the processing target object; recess-shaped supporting body accommodating portions formed on a top surface of the support main body; and supporting bodies accommodated in the respective supporting body accommodating portions to be protruded above the top surface of the support main body, the supporting bodies being rockable in the supporting body accommodating portions while supporting the processing target object of which bottom surface is in contact with upper peak portions of the supporting bodies.

In accordance with still another aspect of the present invention, there is provided a support structure for supporting a processing target object, including: a support main body that supports a weight of the processing target object; recess-shaped supporting body accommodating portions formed on a top surface of the support main body; and supporting bodies accommodated in the respective supporting body accommodating portions to be protruded above the top surface of the support main body, the supporting bodies being rotatably supported in the supporting body accommodating portions while supporting the processing target object of which bottom surface is in contact with upper peak portions of the supporting bodies.

In accordance with still another aspect of the present invention, there is provided a load lock apparatus connected between a vacuum chamber and an atmospheric chamber via gate valves and capable of selectively creating therein a vacuum atmosphere and an atmospheric atmosphere, the apparatus including: a load lock chamber capable of being evacuated to a vacuum level and returned back into an atmospheric pressure; the support structure described above provided in the load lock chamber; a heat source for heating and/or cooling the processing target object; a lifter mechanism that places the processing target object on the support main body and moves the processing target object away from the support main body; and a gas exhaust unit that evacuates an internal atmosphere of the load lock chamber to vacuum.

In accordance with still another aspect of the present invention, there is provided a load lock apparatus connected between a vacuum chamber and an atmospheric chamber via gate valves and capable of selectively creating therein a vacuum atmosphere and an atmospheric atmosphere, the apparatus including: a load lock chamber; the supporting structure described above provided in a plural number; a supporting unit having the supporting structures provided in the load lock chamber to support a multiple number of processing target objects in multiple levels; a gas introduction unit having gas injection openings provided to correspond to the support structures to introduce an atmospheric pressure restoring gas as a cooling gas; and a gas exhaust unit that evacuates an internal atmosphere of the load lock chamber to a vacuum level.

In accordance with still another aspect of the present invention, there is provided a processing apparatus for performing a predetermined process on a processing target object, including: a processing chamber that accommodates the processing target object therein; the support structure described above provided within the processing chamber; a heating unit that heats the processing target object; a lifter mechanism that places the processing target object on the support main body and moves the processing target object away from the support main body; a gas supply unit that supplies a processing gas into the processing chamber; and a gas exhaust unit that evacuates an internal atmosphere of the processing chamber to vacuum.

In accordance with still another aspect of the present invention, there is provided a transfer mechanism for transferring a processing target object, including: an arm member configured to be capable of making an extending/retracting motion and a rotating motion; and the support structure described above provided on a leading end of the arm member.

### BRIEF DESCRIPTION OF THE DRAWINGS

The objects and features of the present invention will become apparent from the following description of embodiments, given in conjunction with the accompanying drawings, in which:

FIG. 1 is a schematic plan view illustrating a general processing system including a load lock apparatus having a support structure in accordance with an embodiment of the present invention;

FIG. 2 sets forth a schematic cross sectional view illustrating the processing system shown in FIG. 1;

FIG. 3 is a cross sectional view illustrating the support structure provided in the load lock apparatus in accordance with the embodiment of the present invention;

FIG. 4 provides a plane view illustrating a support main body of the support structure;

FIGS. 5A and 5B are respectively an enlarged cross sectional view and an enlarged plane view illustrating a single supporting body unit formed on a surface of the support main body;

FIG. 6 illustrates a support structure in accordance with a first modification of the embodiment of the present invention;

FIGS. 7A and 7B illustrate a support structure in accordance with a second modification of the embodiment of the present invention;

FIG. 8 is an enlarged cross sectional view illustrating a supporting body unit of a support structure in accordance with a third modification of embodiment of the present invention;

FIG. 9 is an enlarged cross sectional view illustrating a supporting body unit of a support structure in accordance with a fourth modification of the embodiment of the present invention;

FIGS. 10A and 10B are enlarged cross sectional views illustrating a supporting body unit of a support structure in accordance with a fifth modification of the embodiment of the present invention;

FIGS. 11A and 11B illustrate a supporting body unit of a support structure in accordance with a sixth modification of the embodiment of the present invention;

FIGS. 12A and 12B illustrate a supporting body unit of a support structure in accordance with a seventh modification of the embodiment of the present invention;

FIGS. 13A and 13B illustrate a supporting body unit of a support structure in accordance with an eighth modification of the embodiment of the present invention;

FIGS. 14A and 14B illustrate an enlarged cross sectional view illustrating a supporting body unit of a support structure in accordance with a ninth modification of the embodiment of the present invention;

FIGS. 15A and 15B illustrate a supporting body unit of a support structure in accordance with a tenth modification of the embodiment of the present invention;

FIGS. 16A and 16B illustrate a supporting body unit of a support structure in accordance with an eleventh modification of the embodiment of the present invention;

FIG. 17 is a table showing the number of measured particles;

FIG. 18 shows electron micrographs illustrating examples of rear surface states of a semiconductor wafer in contact with a supporting body;

FIG. 19 presents a perspective view illustrating a modification example of a support main body of a supporting structure in accordance with the present invention;

FIG. 20 provides a schematic plane view illustrating a state in which the support structure in accordance with the embodiment of the present invention is applied to a first transfer mechanism provided in a transfer chamber;

FIGS. 21A and 21B show a pick shape in accordance with a first modified example of the pick shown in FIG. 20;

FIGS. 22A and 22B show a pick shape in accordance with a second modified example of the pick shown in FIG. 20;

FIG. 23 presents a longitudinal cross sectional view illustrating a load lock apparatus to which a support structure in accordance with the present invention is applied and which is configured to accommodate a multiple number of wafers;

FIG. 24 sets forth an enlarged partial cross sectional view illustrating a supporting unit that supports a processing target object;

FIG. 25 is a plane view illustrating an example of a supporting member of the supporting unit;

FIG. 26 depicts an enlarged cross sectional view illustrating a supporting unit of a load lock apparatus in accordance with a modification of the embodiment of the present invention;

FIGS. 27A and 27B show a lifter mechanism to which a support structure in accordance with the embodiment of the present invention is applied;

FIG. 28 is a view for describing an operation of the lifter mechanism shown in FIG. 27;

FIG. 29 presents a perspective view illustrating a mounting table of a semi-batch type processing apparatus to which a support structure in accordance with the embodiment of the present invention is applied;

FIGS. 30A and 30B are partial cross sectional views illustrating a part of the mounting table of the processing apparatus shown in FIG. 29; and

FIG. 31 is a schematic configuration view illustrating a conventional load lock apparatus.

### DETAILED DESCRIPTION OF THE EMBODIMENTS

Hereinafter, a support structure, a load lock apparatus, a processing apparatus and a transfer mechanism in accordance with embodiments of the present invention will be described in detail with reference to the accompanying drawings which form a part hereof.

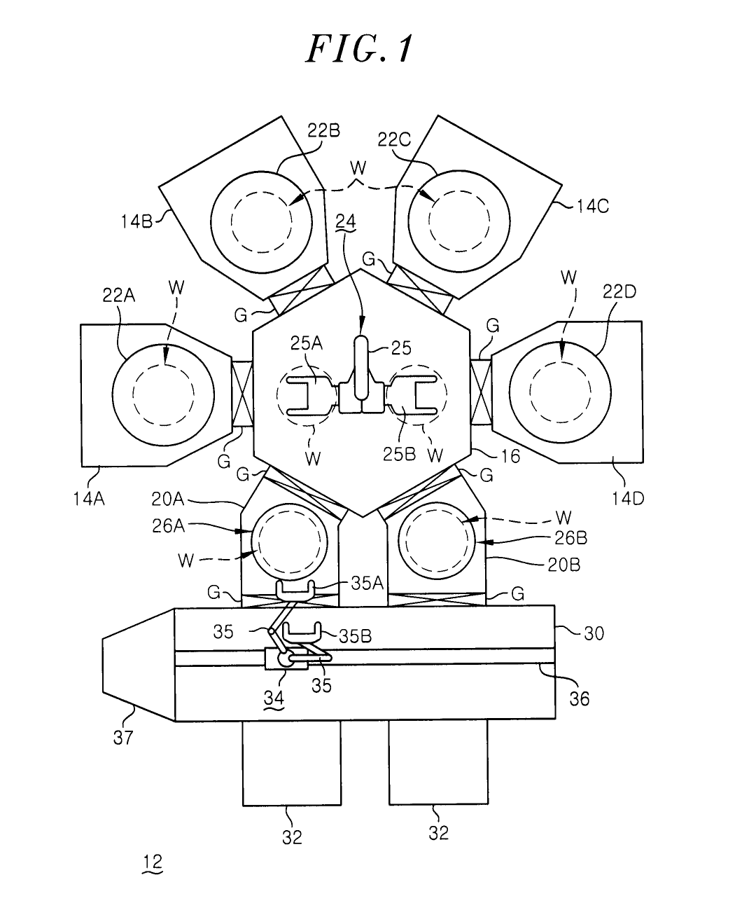

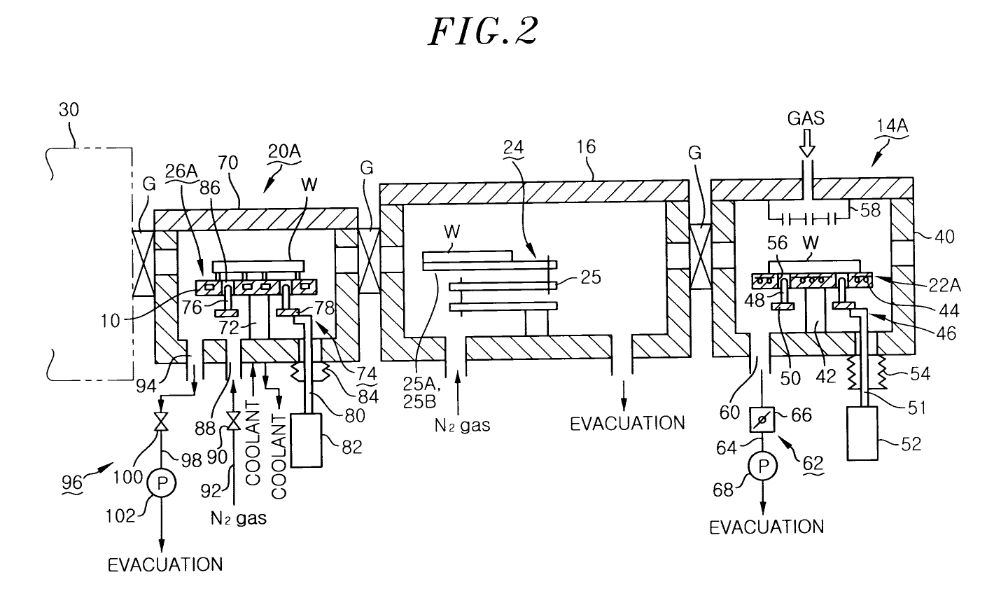

First, an example of a processing system including a processing apparatus and a load lock apparatus having a support structure in accordance with an embodiment will be described. As shown in FIGS. 1 and 2, the processing system 12 includes four vacuum-evacuable processing apparatuses 14A to 14D. The processing apparatuses 14A to 14D serve as various processing apparatuses that perform various processes such as a film forming process and an etching process in vacuum atmosphere. The processing apparatuses 14A to 14D are connected to a hexagonal vacuum-evacuable transfer chamber 16 via respective gate valves G. Further, the processing system 12 also includes load lock apparatuses 20A and 20B for transferring a semiconductor wafer W as a processing target object into the transfer chamber 16 while maintaining a vacuum atmosphere in the transfer chamber 16. The load lock apparatuses 20A and 20B are connected to the transfer chamber 16 via respective gate valves G.

Mounting tables 22A to 22D, each of which is configured to mount thereon a semiconductor wafer W, are provided in the processing apparatuses 14A to 14D, respectively. Further, an extensible, retractable and rotatable first transfer mechanism 24 is provided in the transfer chamber 16 to transfer semiconductor wafers W among the processing apparatuses 14A to 14D and between the processing apparatuses 14A to 14D and the load lock apparatuses 20A and 20B. Specifically, the first transfer mechanism 24 mainly includes an arm member 25 configured to be capable of making an extending/retracting motion and a rotating motion; and two picks 25A and 25B provided at leading ends of the arm member 25. A semiconductor wafer W is transferred as described above by being directly held on either one of the picks 25A and 25B.

Further, support structures 26A and 26B configured to temporarily hold semiconductor wafers W thereon are provided in the load lock apparatuses 20A and 20B, respectively. The support structures 26A and 26B will be described later. Further, a horizontally elongated loading module 30 is connected to a side of the load lock apparatuses 20A and 20B that is opposite to the side thereof connected to the transfer chamber 16, via respective gate valves G. I/O ports 32, each of which is configured to mount thereon a cassette (not shown) capable of accommodating a multiple number of semiconductor wafers therein, are provided at another side of the loading module 30. Further, an extensible, retractable and rotatable second transfer mechanism 34 is provided in the loading module 30.

Specifically, the second transfer mechanism 34 mainly includes an arm member 35 configured to be capable of making an extending/retracting motion and a rotating motion; and two picks 35A and 35B provided at leading ends of the arm member 35. A semiconductor wafer W is transferred by being directly held on either one of the picks 35A and 35B. Further, the second transfer mechanism 34 is movable along a guide rail 36 in a length direction of the loading module 30. An orienter 37 for position alignment and orientation adjustment of a semiconductor wafer W is provided at a lateral side end of the loading module 30. Before the semiconductor wafer W is loaded into any of the processing apparatuses 14A to 14D, position alignment and orientation adjustment of the semiconductor wafer W are performed in the orienter 37.

(Processing Apparatuses)

Here, processing apparatuses will be described with reference to FIG. 2. FIG. 2 illustrates the processing apparatus 14A as a representative of the four processing apparatuses 14A to 14D. The mounting table 22A is provided in the processing apparatus 14A. Further, the load lock apparatus 20A is illustrated in FIG. 2 as a representative of the two load lock apparatuses 20A and 20B.

The processing apparatus 14A includes a box-shaped processing chamber 40 made of, e.g., an aluminum alloy. The mounting table 22A provided in the processing chamber 40 is fixed on an upper end of a supporting column 42 standing upright at a bottom portion of the processing chamber 40. A heating unit 44 made up of, e.g., a resistance heater is embedded in the mounting table 22A to heat a semiconductor wafer W mounted on the mounting table 22A to a predetermined temperature. Further, a lifter mechanism 46 is provided to move up and down the semiconductor wafer W when the semiconductor wafer W is loaded or unloaded.

Specifically, the lifter mechanism 46 includes three elevating pins 48 (only two of them are illustrated in the shown example), and lower ends of the elevating pins 48 are supported by, e.g., a circular arc-shaped elevating plate 50. The elevating plate 50 is supported on an upper end of an elevating rod 51, which is configured to pass through the bottom portion of the processing chamber 40, and the elevating rod 51 is moved up and down by an actuator 52. Further, an expansible/contractible metal bellows 54 is installed to surround a portion of the elevating rod 51 that passes through the chamber bottom portion. Accordingly, the elevating rod 51 can be moved up and down while the inside of the processing chamber 40 is airtightly maintained by the bellows 54.

Further, the mounting table 22A is provided with pin insertion through holes 56 through which the elevating pins are inserted to be moved up and down. When the semiconductor wafer W is loaded or unloaded, the elevating pins 48 are moved up and down so as to be protruded from and retracted into the pin insertion through holes 56. Further, a gas supply unit 58 configured as, e.g., a shower head is provided at a ceiling portion of the processing chamber 40 and supplies a processing gas into the processing chamber 40. The gas supply unit 58 is not limited to the shower head.

Further, a gas exhaust port 60 is provided at a bottom portion of the processing chamber 40, and a gas exhaust unit 62 for evacuating an atmosphere in the processing chamber 40 is connected to the gas exhaust port 60. To be specific, the gas exhaust unit 62 includes a gas passage 64 connected to the gas exhaust port 60, and a pressure control valve 66 for adjusting a pressure inside the processing chamber 40 and a vacuum pump 68 are sequentially installed on the gas passage 64. With this configuration, the inside of the processing chamber 40 can be evacuated to a vacuum level while its internal pressure is adjusted. In the processing apparatus 14A configured as described above, a film forming process may be performed, for example.

Each of the other respective processing apparatuses 14B to 14D may serve as a processing apparatus corresponding to a process that need to be performed on the semiconductor wafer W. Further, each of the other respective processing apparatuses 14B to 14D may serve as a plasma processing apparatus. Further, the transfer chamber 16 connected to the respective processing apparatus 14A to 14D is configured such that an inert gas such as a N₂ gas can be supplied therein, and the inside of the transfer chamber 16 can also be evacuated to the vacuum level. Accordingly, when the processing system is operated, the inside of the transfer chamber 16 is maintained in a vacuum atmosphere.

(Load Lock Apparatuses)

Now, the load lock apparatuses will be described. Since the two load lock apparatuses 20A and 20B have the same configuration, only one load lock apparatus 20A will be described here.

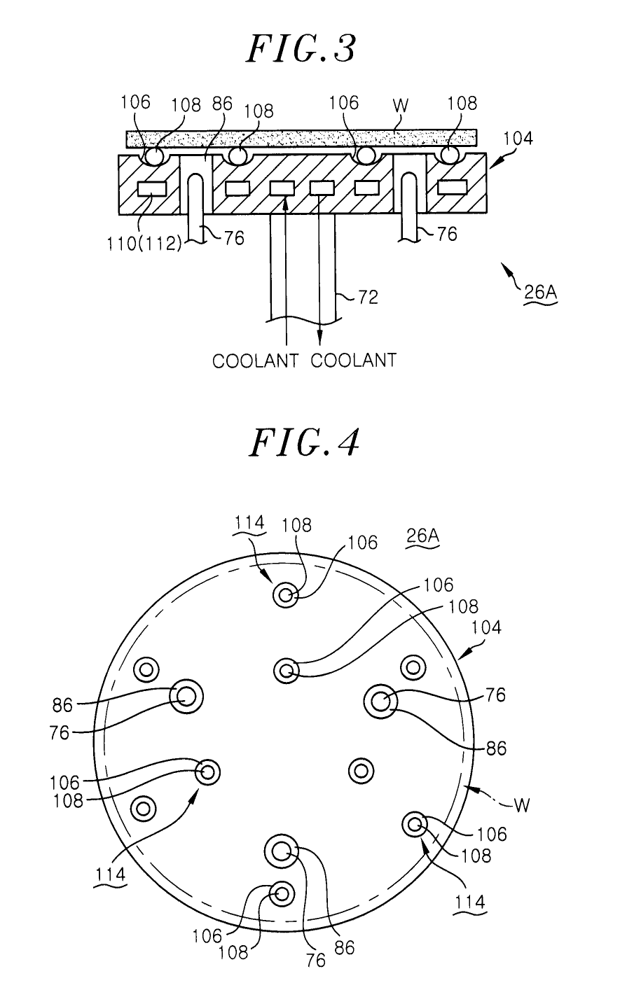

The load lock apparatus 20A includes a box-shaped load lock chamber 70 made of, e.g., an aluminum alloy. The support structure 26A in accordance with the present embodiment provided in the load lock chamber 70 is fixed on an upper end of a supporting column 72 standing upright at a bottom portion of the load lock chamber 70, as shown in FIG. 3. Here, the support structure 26A is formed in a thick circular plate shape having a size slightly greater than that of a semiconductor wafer W. Further, a lifter mechanism 74 is provided to move up and down the semiconductor wafer W when the semiconductor wafer W is loaded or unloaded.

Specifically, the lifter mechanism 74 includes three elevating pins 76 (only two of them are illustrated in the shown example), and lower ends of the elevating pins 76 are supported by, e.g., a circular arc-shaped elevating plate 78. The elevating plate 78 is supported by an upper end of an elevating rod 80, which is configured to pass through the bottom portion of the load lock chamber 70, and the elevating rod 80 is moved up and down by an actuator 82. Further, an expansible/contractible metal bellows 84 is installed to surround a portion of the elevating rod 80 that passes through the chamber bottom portion. Accordingly, the elevating rod 80 can be moved up and down while the inside of the load lock chamber 70 is airtightly maintained.

The support structure 26A is provided with pin insertion through holes 86 through which the elevating pins 76 are inserted. When the semiconductor wafer W is loaded or unloaded, the elevating pins 76 are moved up and down so as to be protruded from and retracted into the pin insertion through holes 86. Further, a gas inlet port 88 is provided at a bottom portion of the load lock chamber 70. A gas inlet passage 92 provided with an opening/closing valve 90 is connected to the gas inlet port 88, and an inert gas such as a N₂ gas can be supplied into the load lock chamber 70 when necessary.

Furthermore, a gas exhaust port 94 is provided at a bottom portion of the load lock chamber 70, and a gas exhaust unit 96 for evacuating an atmosphere in the load lock chamber 70 is connected to the gas exhaust port 94. To be specific, the gas exhaust unit 96 includes a gas passage 98 connected to the gas exhaust port 94. An opening/closing valve 100 and a vacuum pump 102 are sequentially installed on the gas passage 98. With this configuration, the internal atmosphere of the load lock chamber 70 can be evacuated to a vacuum level.

The support structure 26A includes, as illustrated in FIGS. 3 to 5, a support main body 104 that supports a weight of the semiconductor wafer W; supporting body accommodating portions 106 formed in a top surface of the support main body 104; and supporting bodies 108 accommodated in the supporting body accommodating portions 106 and configured to be rollable while supporting the semiconductor wafer W by bringing their upper peaks into contact with the semiconductor wafer W.

Specifically, the support main body 104 is formed in a thick circular plate shape having a diameter slightly larger than that of the semiconductor wafer W, and the top surface of the support main body 104 is formed as a planar surface. The support main body 104 may be made of an aluminum alloy, a nickel alloy, or a ceramic material such as aluminum nitride or alumina. A heat source 110 for heating and/or cooling the semiconductor wafer W is provided in the support main body 104. Here, a cooling jacket 112 through which a coolant flows is buried throughout the substantially entire supporting main body 104 as the heat source 110, and the semiconductor wafer W held on the top surface of the support main body 104 is cooled by cooling effect of the cooling jacket 112.

In case of preheating a semiconductor wafer W to be processed, a resistance heater or the like may be provided as the heat source 110 instead of the cooling jacket 112 so as to heat the semiconductor wafer W. Further, it may be also possible to provide a thermoelectric conversion element such as a peltier element as the heat source 110 to perform the heating and cooling of the semiconductor wafer W selectively by converting a direction of a current flowing in the thermoelectric conversion element as necessary.

The supporting body accommodating portions 106 are formed on the planar top surface of the support main body 104 in recess shapes. In the present embodiment, nine supporting body accommodating portions 106 are provided: three are formed on an intermediate circumference of the support main body 104 at an angular interval of about 120 degrees, and six are formed on an outer circumference of the support main body 104 at an angular interval of about 60 degrees. The number of the supporting body accommodating portions 106 can vary without being limited to nine. The supporting bodies 108 are accommodated in the supporting body accommodating portions 106 in one-to-one correspondence. That is, a single supporting body accommodating portion 106 and a single supporting body 108 accommodated therein form a single supporting body unit 114. In the present embodiment, nine supporting body units 114 are provided.

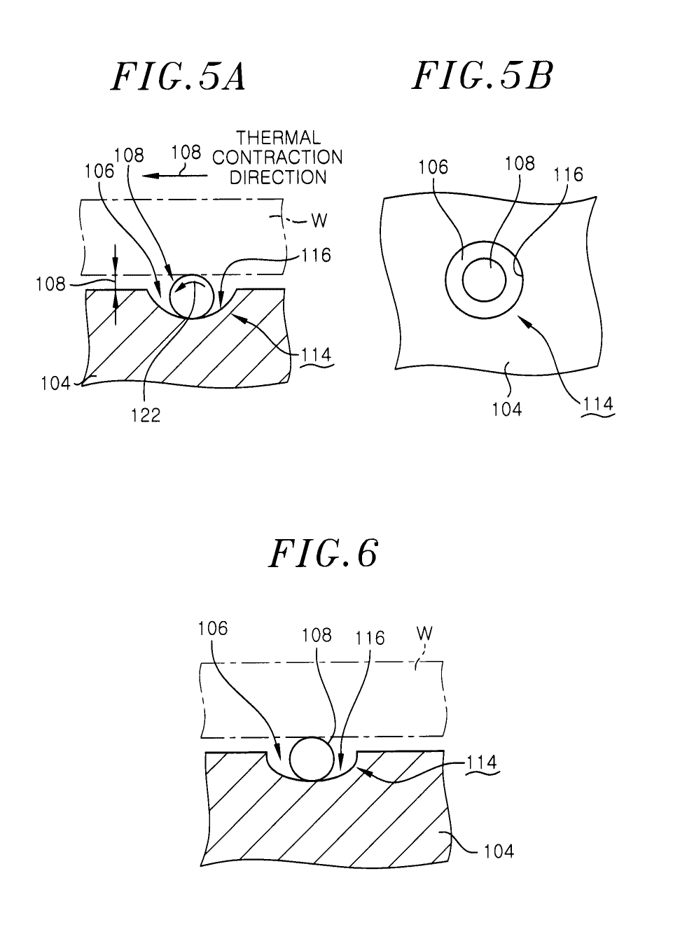

To be specific, each supporting body 108 is formed in a sphere shape having a diameter of about several millimeters ranging from, e.g., about 3 mm to about 7 mm, as depicted in FIG. 5, and the supporting body 108 is configured to be rollable. The diameter of the supporting body 108 can vary without being limited to that in the above example. The spherical supporting body 108 may be made of a heat resistant material, e.g., a ceramic material such as quartz, aluminum nitride, or the like. Alternatively, when the likelihood of metal contamination is low, the supporting body 108 may be made of a metal such as nickel, titanium, or the like.

As stated above, the supporting body 108 supports the semiconductor wafer W thereon while its upper peaks is in contact with a rear surface of the semiconductor wafer W. Accordingly, even in case the semiconductor wafer W thermally expands or contracts, the amount of a thermal expansion/contraction of the semiconductor wafer W may be absorbed as the spherical supporting body 108 rotates.

Further, a bottom surface 116 of each supporting body accommodating portion 106 is formed in a curved shape to allow the supporting body 108 accommodated therein to return to its original position, i.e., to a starting point by its own gravity when the semiconductor wafer W is separated from the supporting body 108. To elaborate, the bottom surface 116 of the supporting body accommodating portion 106 is formed in a curved surface shape of which central portion is lowest, and this central portion serves as the original position (starting point) of the supporting body 108. The curved surface of the bottom surface 116 of the supporting body accommodating portion 106 may have a round shape same as a part of a surface of a sphere having a radius larger than that of the supporting body 108 and may have a circular arc-shaped cross section.

In this case, a length L1 between the upper peak point of the supporting body 108 and a horizontal level of the top surface of the support main body 104 when the supporting body 108 is located at the starting point which is the central portion of the supporting body accommodating portion 106 is set to be several millimeters ranging from, e.g., about 0.3 mm to about 2.0 mm. In such a case, the radius of the supporting body accommodating portion 106 having the circular arc-shaped cross section is set to range from, e.g., about 3 mm to about 10 mm.

Since a thermal contraction amount in the size of the semiconductor wafer W ranges from about 0.1 mm to about 0.4 mm, a rotation angle of the supporting body 108 corresponding to this length would be very small. Thus, the supporting body 108 is prevented from rolling out of the supporting body accommodating portion 106.

Hereinafter, a part of operation of the processing system 12 having the above-described configuration will be schematically explained. First, an unprocessed semiconductor wafer W is loaded into the loading module 30 by the second transfer mechanism 34 from a cassette container (not shown) provided in an I/O port 32. Then, the semiconductor wafer W is transferred into the orienter 37 provided at the end of the lateral side of the loading module 30, and position and orientation of the semiconductor wafer W are adjusted in the orienter 37. The semiconductor wafer W may be made of, e.g., a silicon substrate.

After the position alignment and the orientation adjustment are completed, the semiconductor wafer W is transferred again by the second transfer mechanism 34 into either one of the two load lock apparatuses 20A and 203. After the inside of the corresponding load lock apparatus is evacuated to the vacuum level, the semiconductor wafer W is transferred into the transfer chamber 16 from the load lock apparatus by the first transfer mechanism 24 in the transfer chamber 16 which is previously evacuated to the vacuum level.

Then, the unprocessed semiconductor wafer W loaded into the transfer chamber 16 is transferred by the first transfer mechanism 24 into the processing apparatuses 14A to 14D in sequence as required, and various predetermined processes are performed in the processing apparatuses 14A to 14D. For example, a film forming process, an etching process, an oxidation/diffusion process, and the like may be performed on the semiconductor wafer W. Here, depending on the kind of the processes performed on the semiconductor wafer W, the semiconductor wafer W becomes to have a high temperature ranging from, e.g., about 300° C. to about 700° C.

After all the necessary processes are performed on the semiconductor wafer W, the processed semiconductor wafer W in the high temperature state is loaded into either one of the load lock apparatuses 20A and 20B by the first transfer mechanism 24 and is cooled therein to a safe temperature, e.g., about 100° C. or thereabout. While the cooling of the semiconductor wafer W is carried out, the inside of the load lock apparatus that accommodates the semiconductor wafer W therein is returned back into the atmospheric pressure from the vacuum atmosphere. After the load lock apparatus being turned into the atmospheric pressure, the semiconductor wafer W is transferred into the loading module 30 from the load lock apparatus by the second transfer mechanism 34 and then is accommodated in a cassette container (not shown) for accommodating processed semiconductor wafers provided on an I/O port 32.

Here, an operation in the load lock apparatus 20A for cooling the semiconductor wafer W will be explained. The same cooling operation may be performed in the other load lock apparatus 20B as well. First, as depicted in FIGS. 2 and 3, while the processed semiconductor wafer W in the high temperature state is cooled, a coolant is flowed in the cooing jacket 112 provided in the support structure 26A of the load lock apparatus 20A. Then, by moving the elevating pins 76 of the lifter mechanism 74 up and down, the semiconductor wafer W in the high temperature state is mounted on the top surface of the support main body 104. A rear surface of the semiconductor wafer W comes into contact with the upper peaks of the spherical supporting bodies 108 respectively accommodated in the nine supporting body accommodating portions 106 of the support main body 104 and is supported by the supporting bodies 108.

Then, while the gate valves G on the side of the transfer chamber 16 and on the side of the loading module 30 are both kept closed, a N₂ gas is introduced into the load lock chamber 70, and the semiconductor wafer W in the high temperature state is gradually cooled by cooling effect of the cooling jacket 112 in the support main body 104. That is, the heat of the semiconductor wafer W is conducted and/or radiated to the support main body 104 in a cooled state by heat radiation and/or heat conduction, so that the semiconductor wafer W is cooled.

As the semiconductor wafer W is cooled, the semiconductor wafer W is thermally contracted. Such a thermal contraction may occur dominantly in a direction toward a center of the semiconductor wafer W. In FIG. 5A, it is assumed that the semiconductor wafer W is thermally contracted in the direction of an arrow ‘120’, for example. Though the length of the thermal contraction may differ depending on the temperature of the semiconductor wafer W, the length may be ranging from, e.g., about 0.1 mm to about 0.4 mm.

In a conventional support structure as shown in FIG. 31, a rear surface of the semiconductor wafer W and an upper peak of a supporting pin 80 are rubbed against each other when the thermal contraction occurs, resulting in a scratch or a flaw on the rear surface of the semiconductor wafer W. In accordance with the present embodiment, the spherical supporting body 108 rolls slightly in the direction of an arrow ‘122’ in FIG. 5A and, thus, the thermal contraction amount of the semiconductor wafer W can be absorbed. As a result, friction between the rear surface of the semiconductor wafer W and the surface of the supporting body 108 may be suppressed, so that formation of a scratch or a flaw on the rear surface of the semiconductor wafer W can be prevented.

To unload the semiconductor wafer W after the completion of the cooling of the semiconductor wafer W, the semiconductor wafer W is separated from the supporting body 108 by being lifted upward by the elevating pins 76, and the spherical supporting body 108 rolls by its own gravity on the bottom surface 116 of the supporting body accommodating portion 106 having the circular arc-shaped cross section and returns to its original position, i.e., to a central starting point. Accordingly, every time a semiconductor wafer W is unloaded after the completion of the cooling operation, the spherical supporting body 108 constantly returns to its original position, and the above-described operation can be performed continuously.

In general, depending on a temperature distribution of the semiconductor wafer W, the semiconductor wafer W may be contracted in all directions as well as in the direction toward its center. Even in such a case, the spherical supporting body 108 may roll in a direction in which thermal contraction occurs, so that the thermal contraction amount of the semiconductor wafer W can be still absorbed. Thus, formation of a scratch or a flaw on the rear surface of the semiconductor wafer W can be prevented.

Further, although the above embodiment have been described for the case of cooling the processed semiconductor wafer W in the high temperature state, a heating unit may be provided in the support structure of the load lock apparatus to preheat an unprocessed semiconductor wafer of a room temperature in order to improve throughput. Even in case where the preheating is performed, the support structure in the above-described embodiment may be used (in this case, the heating unit such as a heater may be used as the heat source 110). Accordingly, formation of a scratch or a flaw on the rear surface of the semiconductor wafer W can be suppressed in the same manner as described above even when the semiconductor wafer thermally expands.

In accordance with the above embodiment, in the support structure for supporting a processing target object such as a semiconductor wafer W, the recess-shaped supporting body accommodating portions 106 are formed in the top surface of the support main body 104 configured to support a weight of the processing target object. Further, the respective supporting bodies 108 are rollably accommodated in the supporting body accommodating portions and are configured to support the processing target object while their upper peaks are in contact with a rear surface of the processing target object. Thus, when the processing target object such as the semiconductor wafer W is supported on the support structure, formation of a scratch or a flaw on a rear surface (bottom surface) of the processing target object can be suppressed even in case thermal expansion or contraction of the processing target object occurs by heating or cooling, for example.

(First Modification)

The cross sectional shape (curved shape) of the bottom surface 116 of the supporting body accommodating portion 106 may not be limited to the circular arc shape (round shape). For example, in a support structure in accordance with a first modification as illustrated in FIG. 6, a bottom surface 116 of a supporting body accommodating portion 106 may be formed to have an elliptical arc-shaped cross section. Further, as long as the supporting body accommodating portion 106 has a curved surface shape of which central portion is formed lowest (deepest) and as long as a supporting body 108 is allowed to be returned to its original position by its own gravity when the semiconductor wafer W is separated from the supporting body 108, the supporting body accommodating portion 106 may have various curved surface shapes without being limited to the shapes in the aforementioned embodiment.

(Second Modification)

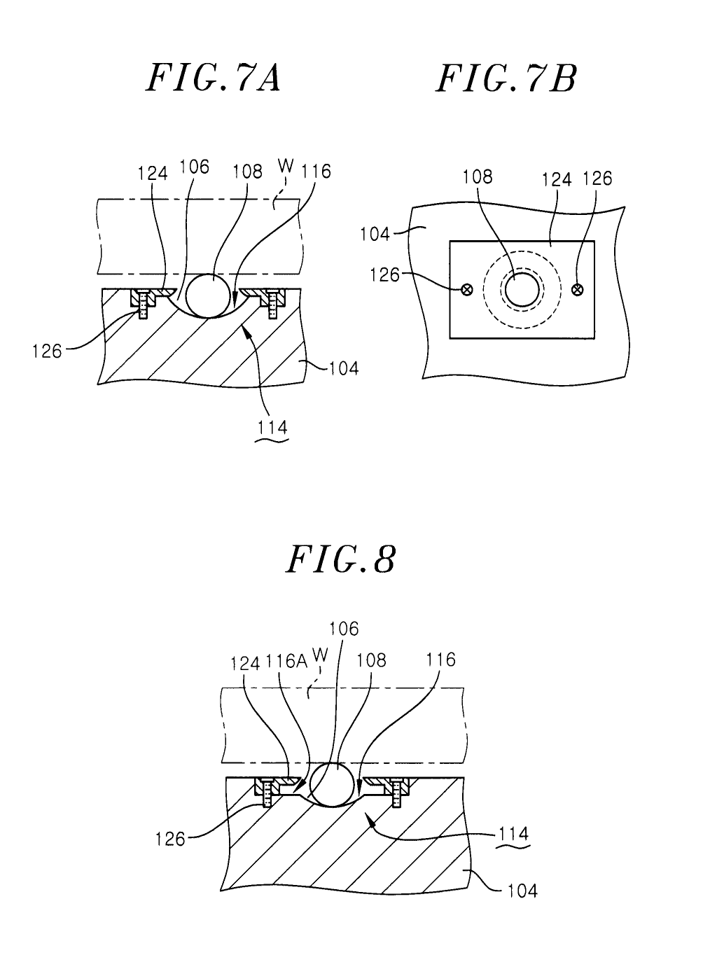

A support structure in accordance with a second modification of the present embodiment will be described. In the above-described embodiment and modification, the spherical supporting body 108 may jump out of the supporting body accommodating portion 106 by an effect of a static electricity charged in a semiconductor wafer W or by an impact applied to the supporting body 108. Therefore, a jump-out preventing cover member may be provided. FIGS. 7A and 7B illustrate a supporting structure having such a jump-out preventing cover member in accordance with the second modification. FIG. 7A is an enlarged cross sectional view illustrating a supporting body unit, and FIG. 7B is a plane view thereof. Further, in FIGS. 7A and 7B, like reference numerals will be given to like parts described in FIGS. 1 to 6, and redundant description thereof will be omitted.

As illustrated in FIGS. 7A and 7B, a ring-shaped jump-out preventing cover member 124 is fixed in an opening of a supporting body accommodating portion 106 by screws 126 or the like. The ring-shaped jump-out preventing cover member 124 is extended from the opening of the supporting body accommodating portion 106 toward a horizontal center thereof. An opening of the jump-out preventing cover member 124 has a diameter slightly smaller than that of the spherical supporting body 108, and the jump-out preventing cover member 124 is positioned close to the supporting body 108 as long as it does not interfere with the roll of the supporting body 108 when the semiconductor wafer W thermally expands or contracts. To be specific, when the diameter of the supporting body 108 is, e.g., about 5 mm, the opening diameter of the jump-out preventing cover member 124 may be, e.g., about 4.5 mm. In this example, a supporting body unit 114 includes the jump-out preventing cover member 124 in addition to the supporting body accommodating portion 106 and the supporting body 108.

Further, in each of modifications to be described below, an opening of a jump-out preventing cover member 124 and a spherical supporting body 108 may have the same relationship as stated above, so that jump-out of the supporting body can be prevented. With this configuration, even in case the spherical supporting body 108 rolls to jump out of the supporting body accommodating portion 106, the jump-out of the supporting body 108 may be suppressed by the jump-out preventing cover member 124.

(Third Modification)

Next, a support structure in accordance with a third modification of the present embodiment will be explained. In the above-described embodiment and modifications, if particles such as dust enter the supporting body accommodating portion 106, the particles may be dominantly deposited in a lowest (deepest) portion on the bottom surface 116 of the supporting body accommodating portion 106, hampering the roll of the supporting body 108. Therefore, a particle deposit surface may be provided in the supporting body unit 114. FIG. 8 is an enlarged cross sectional view illustrating a supporting body unit of a support structure having such a particle deposit surface in accordance with the third modification of the present embodiment. In FIG. 8, like reference numerals will be given to like parts described in FIGS. 1 to 7B, and redundant description thereof will be omitted.

As illustrated in FIG. 8, a particle deposit surface 116A is horizontally formed around a bottom surface 116 of a supporting body accommodating portion 106 to make particles entered the supporting body accommodating portion 106 be accumulated thereon. Further, a jump-out preventing cover member 124 is fixed at a periphery of the particle deposit surface 116A by screws 126. With this configuration, when particles enter the supporting body accommodating portion 106, the particles may be accumulated on the particle deposit surface 116A, so that the particles are prevented from being dominantly deposited in the center of the supporting body accommodating portion 106. Furthermore, the particle deposit surface 116A may also be applied to the aforementioned embodiment and modifications in which the jump-out preventing cover member 124 is not provided.

(Fourth Modification)

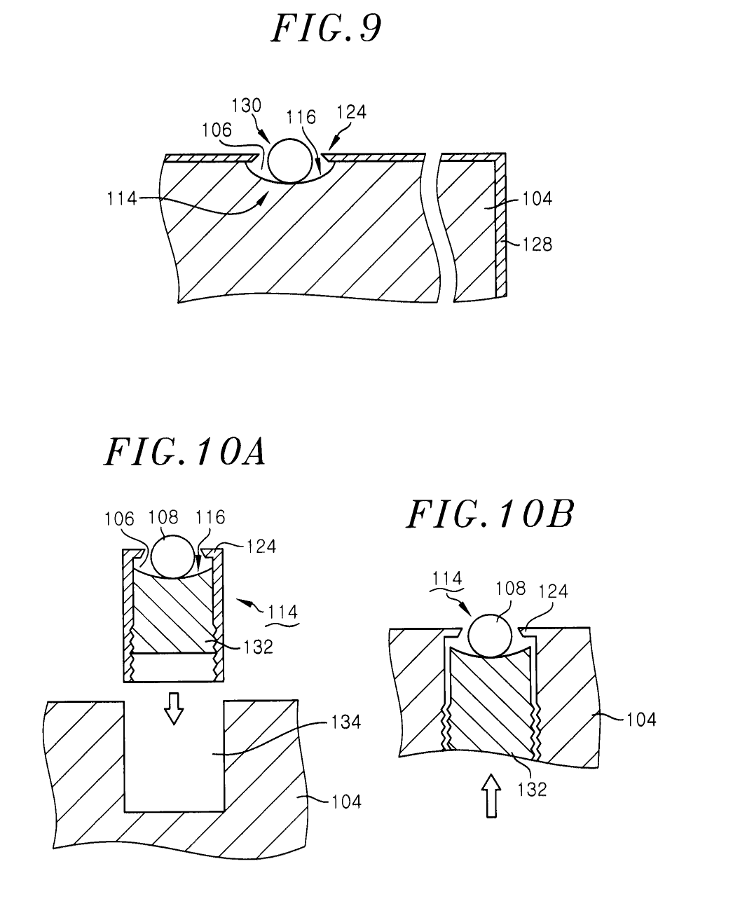

Although the jump-out preventing cover member 124 is fixed to the support main body 104 by the screws 126 in the second and third modifications, the present embodiment is not limited thereto. As depicted in an enlarged cross sectional view shown in FIG. 9 illustrating a supporting body unit of a support structure in accordance with a fourth modification, a thin surface cover body 128 covering a top surface and a side surface of a support main body 104 as one body may be provided. The surface cover body 128 is provided with an opening 130, which is formed at a portion corresponding to the supporting body accommodating portion 106 while allowing an upper peak portion of a supporting body 108 to be projected and exposed above a horizontal surface of the surface cover body 128. This surface cover member 128 may serve as the jump-out preventing cover member 124. The surface cover body 128 may be made of a metal such as aluminum, stainless steel, nickel, titanium or like, a glass material such as quartz glass, ceramic such as aluminum nitride, or the like.

(Fifth Modification)

Next, a support structure in accordance with a fifth modification of the present embodiment will be described. The jump-out preventing cover member 124 is fixed to the support main body 104 by the screws 126 and the supporting body accommodating portion 106 is directly formed on the support main body 104 in the second and third modifications. However, the present embodiment is not limited thereto. The jump-out cover member 124 and the supporting body accommodating portions 106 may be detachably attached to the support main body 104 along with the supporting body 108. FIGS. 10A and 10B are enlarged cross sectional views illustrating a detachable supporting body unit 114 of a support structure in accordance with the fifth modification of the present embodiment.

As depicted in FIG. 10A, the detachable supporting body unit 114 includes a jump-out preventing cover member 124 formed in a cylindrical body shape having an open bottom; an insertion piece 132 having a supporting body accommodating portion 106 formed on a top end thereof and forcibly inserted into the cylindrical jump-out preventing cover member 124; and a spherical supporting body 108 accommodated in the supporting body accommodating portion 106. A hole 134 having a size capable of accommodating the cylindrical jump-out preventing cover member 124 therein is formed in a support main body 104, and the detachable supporting body unit 114 is inserted into the hole 134. Further, as depicted in FIG. 10B, the jump-out preventing cover member 124 may be formed at a top opening of the hole 134 of the support main body 104. In this case, a male screw portion is formed on an outer surface of the insertion piece 132, and a female screw portion is formed on an inner surface of the hole 134. The hole 134 is vertically elongated downward, and the insertion piece 132 with the supporting body 108 supported on an upper end thereof may be inserted into the hole 134 from below the hole 134. In the case of FIGS. 10A and 10B, a successful function of the jump-out preventing cover member 124 can also be achieved.

(Sixth and Seventh Modifications)

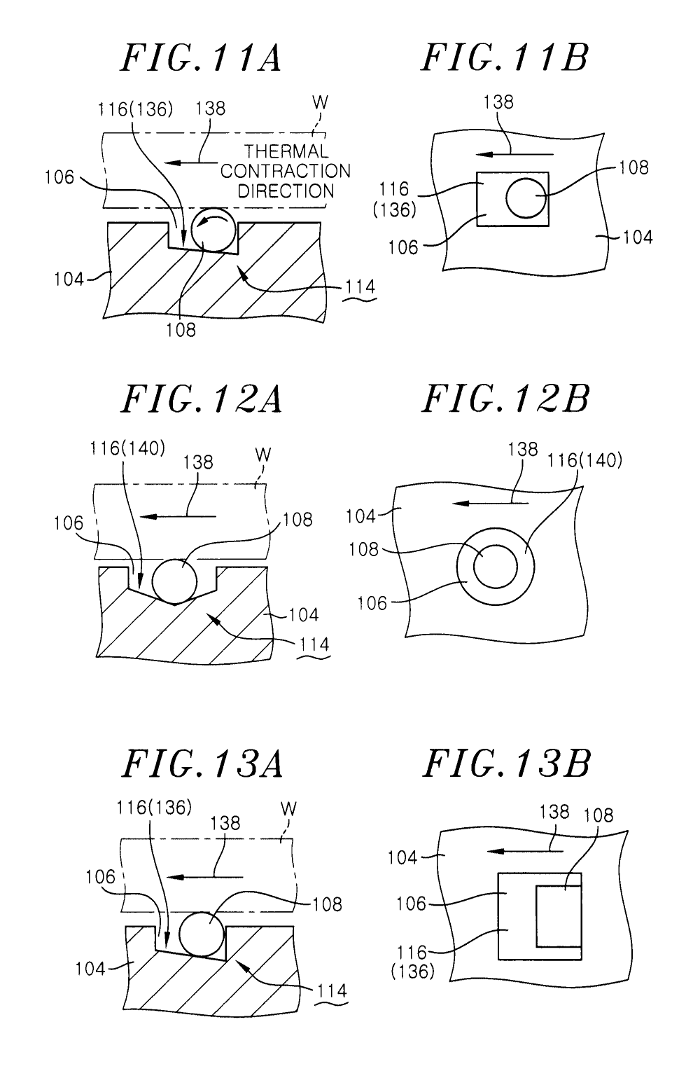

Next, support structures in accordance with a sixth and a seventh modification of the present embodiment will be described. In each of the aforementioned embodiment and modifications, the curved shape of the bottom surface 116 of the supporting body accommodating portion 106 has been described to have, e.g., the circular arc-shaped cross section or the elliptical arc-shaped cross section. However, the shape of the bottom surface 116 may not be limited thereto, and the bottom surface 116 may be formed as an inclined surface with respect to a thermal expansion/contraction direction or may be formed in a conical shape. FIGS. 11A and 11B illustrate a supporting body unit of a support structure in accordance with the sixth modification: FIG. 11A is an enlarged cross sectional view and FIG. 11B is a plane view. FIGS. 12A and 12B depict a supporting body unit of a support structure in accordance with the seventh modification: FIG. 12A is an enlarged cross sectional view and FIG. 12B is a plane view. Like reference numerals will be given to like parts described in the aforementioned embodiment and modifications, and redundant description thereof will be omitted.

In the sixth modification as depicted in FIGS. 11A and 11B, a bottom surface 116 of a supporting body accommodating portion 106 is inclined with respect to a thermal expansion/contraction direction. For example, in this modification, the bottom surface 116 is configured as an inclined surface 136 inclined with respect to a horizontal direction at an angle ranging from about 1° to about 10°, and a lower end side of the inclined surface 136 is configured as an original position (starting point) to which a spherical supporting body 108 would roll back. Further, the inclined surface 136 is inclined such that an upper end of the inclined surface 136 is positioned on the side of the center of the support main body 104 while a lower end of the inclined surface 136 is positioned on the side of the periphery of the support main body 104. In this embodiment, if a semiconductor wafer W thermally contracts in a direction indicated by an arrow 138, the amount of a thermal contraction can be absorbed by rolling up the supporting body 108 on the inclined surface 136. Then, if the semiconductor wafer W is separated from the supporting body 108, the spherical supporting body 108 may roll down the inclined surface 136 and return back to its original position by its own gravity.

Accordingly, formation of a scratch, a flaw, or the like on the rear surface of the semiconductor wafer W can be still suppressed. Further, when the semiconductor wafer W is pre-heated, the semiconductor wafer W may be thermally expanded by the heating. Thus, the inclined surface 136 serving as the bottom surface 116 of the support main body 104 may be inclined in the reverse direction as described above. That is, a lower end of the inclined surface 136 may be positioned on the side of the center of the support main body 104 while an upper end of the inclined surface 136 may be positioned on the side of the periphery of the support main body 104. Even in such a case, formation of a scratch, a flaw, or the like on the rear surface of the semiconductor wafer W can be still suppressed.

In the seventh modification illustrated in FIGS. 12A and 12B, a bottom surface 116 of a supporting body accommodating portion 106 is configured as a conical surface 140 inclined with respect to a horizontal direction at an angle ranging from about 1° to about 10°, for example. The center of the conical surface 140 is configured as an original position (starting point) to which a spherical supporting body 108 would roll back. Accordingly, the supporting body 108 can roll in any directions from the center of the conical surface 140.

In this embodiment, if a semiconductor wafer W is thermally contracted in a direction indicated by an arrow 138, the amount of a thermal contraction may be absorbed by rolling up the spherical supporting body 108 on the conical surface 140 from the starting point at the center of the conical surface 140. Then, if the semiconductor wafer W is separated from the supporting body 108, the supporting body 108 may roll down on the conical surface 140 toward the starting point at the center of the conical surface 140 and return back to its original position by its own gravity. In this case, since the conical surface 140 has a triangle cross section, the spherical supporting body 108 may be located at the center of the supporting body accommodating portion 106 as mentioned above, and, thus, the amount of the thermal contraction is absorbed by rolling up the spherical supporting body 108 on the conical surface 140 in all directions on a horizontal plane.

(Eighth Modification)

Now, a support structure in accordance with an eighth modification of the present embodiment will be described. In each of the aforementioned embodiment and modifications, the supporting body 108 has been described to have a sphere shape. However, the supporting body 108 may have, e.g., a cylinder shape without being limited to the sphere shape. FIGS. 13A and 13B illustrate a supporting body unit of a support structure in accordance with the eighth modification of the present embodiment: FIG. 13A is an enlarged cross sectional view and FIG. 13B is a plane view. Like reference numerals will be given to like parts described in the aforementioned embodiment and modifications, and redundant description thereof will be omitted.

In the eighth modification as depicted in FIGS. 13A and 13B, a supporting body 108 has a cylinder shape having the same diameter as that of the spherical support body as described above. A bottom surface 116 of a supporting body accommodating portion 106 is inclined along the direction of thermal contraction. Here, as in the case shown in FIGS. 11A and 11B, the bottom surface 116 of the supporting body accommodating portion 106 is configured as an inclined surface 136 that is inclined with respect to a horizontal direction at an angle ranging from about 1° to about 10°, for example, and a lower end side of the inclined surface 136 is configured as an original position (starting point) to which the cylindrical supporting body 108 rolls back. The inclined surface 136 is inclined such that an upper end of the inclined surface 136 is positioned on the side of the center of the support main body 104 while a lower end of the inclined surface 136 is positioned on the side of the periphery of the support main body 104. In this modification, if a semiconductor wafer W thermally contracts in a direction indicated by an arrow 138, the amount of thermal contraction can be absorbed by rolling up the cylindrical supporting body 108 on the inclined surface 136. Then, if the semiconductor wafer W is separated from the supporting body 108, the cylindrical supporting body 108 may roll down on the inclined surface 136 and return back to its original position by its own gravity.

Accordingly, with such configuration, formation of a scratch, a flaw, or the like on a rear surface of the semiconductor wafer W can be still prevented. Further, when the semiconductor wafer W is pre-heated, the semiconductor wafer W may be thermally expanded by the heating. Thus, the inclined surface 136 as the bottom surface 116 of the support main body 104 may be inclined in the reverse direction as described above. That is, a lower end of the inclined surface 136 may be positioned on the side of the center of the support main body 104 while an upper end of the inclined surface 136 may be positioned on the side of the periphery of the support main body 104. Even in such a case, formation of a scratch, a flaw or the like on the rear surface of the semiconductor wafer W can be still prevented.

(Ninth Modification)

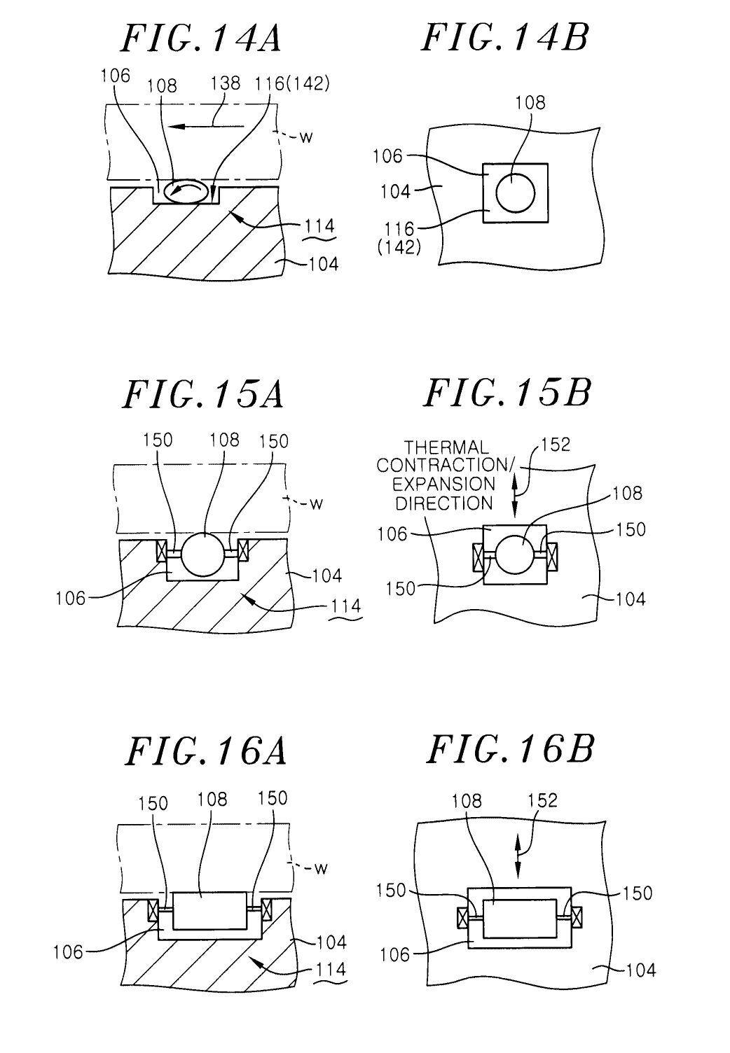

Now, a support structure in accordance with a ninth modification of the present embodiment will be elaborated. In each of the aforementioned embodiment and modifications, the supporting body 108 has been described to have a sphere shape or a cylinder shape. However, the shape of the supporting body 108 may not be limited thereto. In case that a bottom surface of a supporting body accommodating portion is configured as a plane surface, the supporting body 108 may have a shape that allows the supporting body to return back to its original position by its own gravity when a semiconductor wafer is separated from the supporting body. FIGS. 14A and 14B illustrate a supporting body unit of a support structure in accordance with the ninth modification of the present embodiment: FIG. 14A is an enlarged cross sectional view and FIG. 14B is a plane view. Further, like reference numerals will be given to like parts described in the aforementioned embodiment and modifications, and redundant description thereof will be omitted.

In the ninth modification illustrated in FIGS. 14A and 14B, a bottom surface 116 of a supporting body accommodating portion 106 is formed as a horizontal plane surface 142. A supporting body 108 has a circular plane shape and a substantially elliptical cross sectional shape. The supporting body 108 is configured to be rockable such that even if it is inclined in one direction by an external force, it can return back to an original horizontal state when the external force is released. For example, such a shape may be the same as that of a convex lens.

In this modification, if a semiconductor wafer W thermally contracts in a direction indicated by an arrow 138, the amount of a thermal contraction can be absorbed by the elliptical cross sectional shaped supporting body 108 which rocks (inclines) on the plane surface 142. Then, when the semiconductor wafer W is separated from the supporting body 108, the supporting body 108 rocks back to return to its original position, that is, into an original horizontal state by its own gravity.

Accordingly, with such configuration, formation of a scratch, a flaw or the like on a rear surface of the semiconductor wafer W can be still prevented. Further, in this ninth modification, even in case the semiconductor wafer W is pre-heated, the same configuration can be used, and a thermal expansion in any direction on a horizontal plane can be absorbed. Even in this case, the similar effect of preventing formation of a scratch or a flaw on the rear surface of the semiconductor wafer W can be still achieved as in the cases described above. Further, the configurations in accordance with the second to fifth modifications depicted in FIGS. 7A to 10B may be applicable to the configurations in accordance with the sixth to ninth modification shown in FIGS. 11A to 14B.

(Tenth to Eleventh Modification)

Now, support structures in accordance with a tenth modification and an eleventh modification in accordance with the present embodiment will be elaborated. In each of the aforementioned embodiment and modifications, the supporting body 108 has been described to be accommodated in the supporting body accommodating portion 106 such that it can roll or rock therein. However, the present embodiment may not be limited thereto, and the supporting body 108 may be rotatably supported by a rotation shaft. FIGS. 15A and 15B illustrate a supporting body unit of a support structure in accordance with the tenth modification of the present embodiment: FIG. 15A is an enlarged cross sectional view and FIG. 15B is a plane view. FIGS. 16A and 16B illustrate a supporting body unit of a support structure in accordance with the eleventh modification of the present embodiment: FIG. 16A is an enlarged cross sectional view and FIG. 16B is a plane view. Further, like numeral reference will be given to like parts described in the aforementioned embodiment and modifications, and redundant description thereof will be omitted.

In the tenth modification illustrated in FIGS. 15A and 15B, a supporting body 108 is formed in a sphere shape, and in the eleventh modification shown in FIGS. 16A and 16B, a supporting body 108 is formed in a cylinder shape. Each of these supporting bodies 108 is accommodated in a supporting body accommodating portion 106 such that an upper end of the supporting body 108 protrudes higher than a horizontal level of a top surface of a support main body 104, and a rotation shaft 150 is horizontally extended from both ends of the supporting body 108 in a diametric direction. Both ends of the rotation shaft 150 are rotatably supported at the support main body 104. Here, the supporting body 108 is supported in a direction perpendicular to a direction indicated by an arrow 152 which is a thermal expansion/contraction direction of a semiconductor wafer W (i.e., a direction toward the center of the support main body 104 or the center of the semiconductor wafer W supported on the support structure).

In these two modifications, if the semiconductor wafer W thermally contracts in the direction indicated by the arrow 152, the spherical or the cylindrical supporting body 108 may pivotally rotated about the rotation shaft 108 and thus the amount of a thermal contraction can be absorbed by such pivotal rotation. Further, in the above description, although the spherical or the cylindrical supporting body 108 is fixed to the rotation shaft 150, a fixed shaft whose both ends are fastened to the support main body 104 may be provided instead of the rotation shaft 150, and the supporting body 108 may be rotatably attached to the fixed shaft. In such a case, the similar effect as described above may be still obtained.

Accordingly, with such configurations, formation of a scratch, a flaw, or the like on a rear surface of the semiconductor wafer W can be still prevented. Further, when the semiconductor wafer W is pre-heated, the semiconductor wafer W may be expanded by the heating. Thus, the supporting body 108 may be rotated in the reverse direction as stated above. Even in such a case, the effect of preventing formation of a scratch, a flaw, or the like on the rear surface of the semiconductor wafer W can be still obtained.

(Test for Verifying the Support Structures of the Present Embodiment and Modifications)

A test for verifying the support structure of the present embodiment and modifications has been conducted, and a test result will be described below. Here, the test was conducted by applying the support structure in accordance with the second modification shown in FIG. 7 to a load lock apparatus.

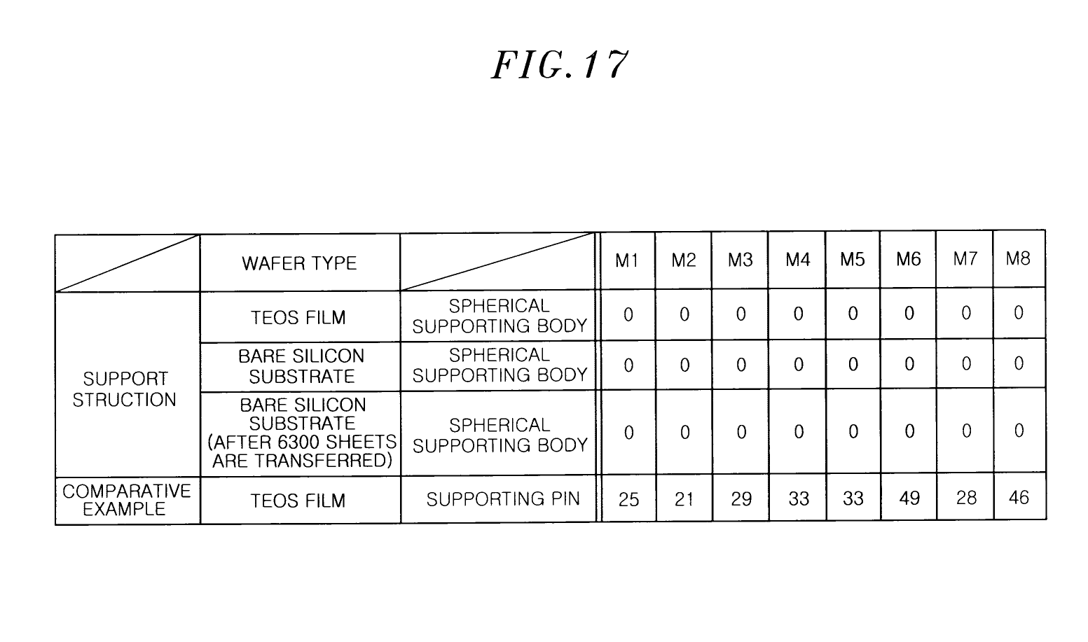

A diameter of the spherical supporting body 108 was about 5 mm; a diameter of the opening of the jump-out preventing cover member 124 was about 4.5 mm; and a radius of a curvature of the bottom surface 116 was about 10 mm. A semiconductor wafer W having a diameter of about 300 mm was used, and a total of nine supporting body units 114 (e.g., three inner supporting units and six outer supporting units) were provided. The semiconductor wafer W was supported by spherical supporting bodies 108 respectively provided in the nine supporting body units, and particles or flaws in an area of about 4 mm² with respect to each of contact points between the semiconductor wafer W and the supporting bodies 108 were observed by a scanning electron microscope (SEM). Used as the semiconductor wafer W were a bare silicon substrate on which no substrate treatment was performed and a silicon substrate on a rear surface of which a TEOS (SiO₂) thin film was formed. The number of measured particles is shown in FIG. 17.

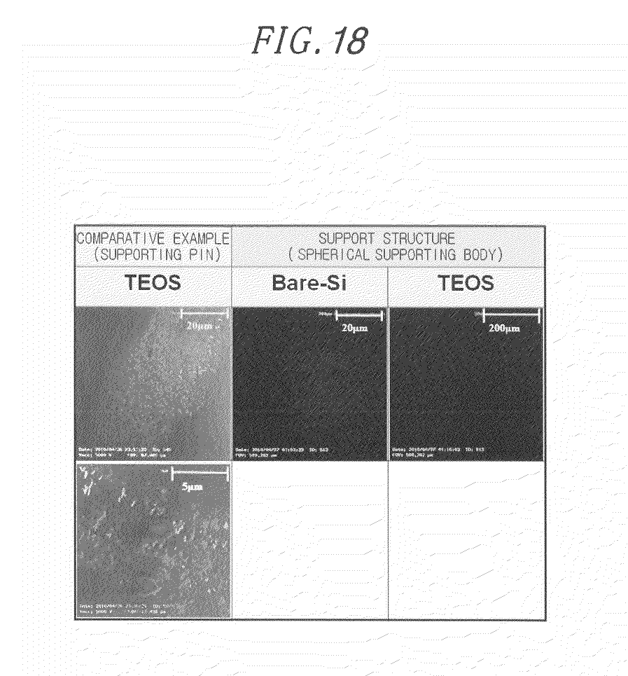

Further, only the particles having a diameter equal to or larger than about 80 nm were counted. FIG. 18 shows electron micrographs illustrating examples of rear surface states of a semiconductor wafer in contact with the supporting bodies. Further, for comparison, the test was also conducted for the support structure having the conventional supporting pins (see FIG. 31) as a comparative example.

In FIG. 17, measurements 1 to 3 (M1 to M3 in FIG. 17) indicate results at contact points of the three inner supporting bodies, and measurements 4 to 8 (M4 to M8 in FIG. 17) indicate results at contact points of the five outer supporting bodies. As for the rest one outer supporting body, since a contact point of the supporting body was wrongly grasped by tweezers during a measurement, the measurement result was regarded as invalid and thus omitted here. Further, for the support structure in accordance with the second modification, the observation was also carried out after 6300 sheets of substrates were transferred.

As shown in FIG. 17, in the comparative example, several tens of particles were observed in all of the measurements 1 to 8, which implies that a great number of particles were generated in the comparative example.

However, in the support structure of the second modification, the counting numbers of particles were all zero in both cases of using the bare silicon substrate and using a silicon substrate having a soft and vulnerable TEOS film on the rear surface thereof. Further, even in case of the observation after the transfer of 6300 sheets of the substrates, the counting numbers of particles were also zero in both cases of using the bare silicon substrate and using the silicon substrate with having the TEOS film on the rear surface thereof. Thus, it has been verified that almost no particles or flaws have been generated on the rear surface of the semiconductor wafer in accordance with the present embodiment and modifications.

Such a result can also be clearly seen from the electron micrographs shown in FIG. 18. In the comparative example, a multiple number of block spot-shaped flaws were observed on the rear surface of the semiconductor wafer W (on a scale of 200 μm), and the presence of such flaws was more apparently observed when the electron microscope was enlarged (on a scale of about 20 μm). To the contrary, in the support structure of the second modification, no flaw was found on the rear surface of the semiconductor wafer (i.e., the rear surface of the semiconductor wafer was seen to be uniformly black on the entire region), which verifies the effectiveness of the support structure of the present embodiment and modifications.

(Modification of the Support Main Body of the Support Structure in the Load Lock Apparatus)

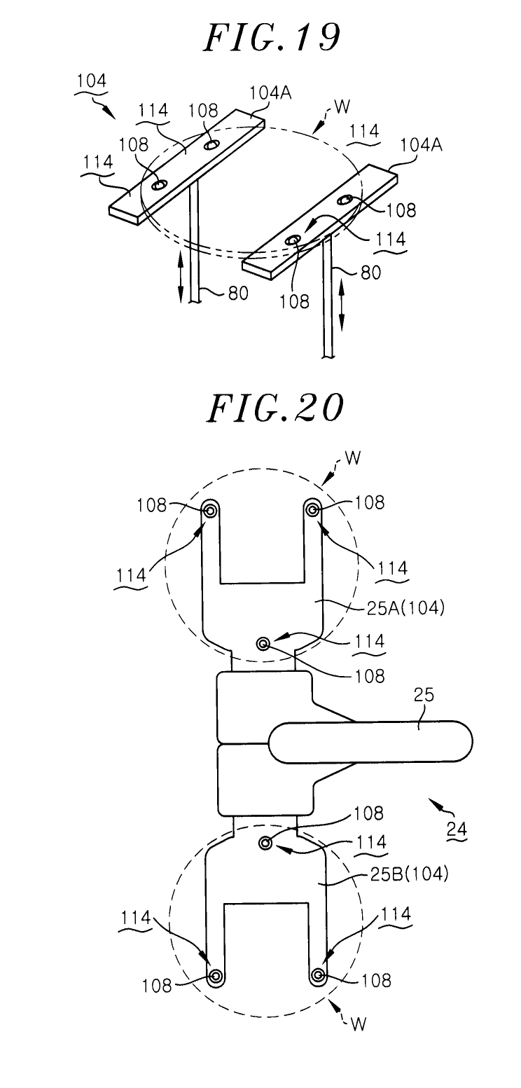

In the above-described load lock apparatus, the support main body used in the support structure is formed as a single body having a circular plate shape. However, the support main body may not be limited thereto, and it may be configured as shown in FIG. 19. FIG. 19 is a perspective view illustrating a modification of the support main body of the support structure. In the following, like reference numerals will be given to like parts described in the above-described embodiment and modifications, and redundant description thereof will be omitted.

A support main body 104 in this load lock apparatus includes two support main body pieces 104A spaced apart from each other in a horizontal direction. Peripheral area of a rear surface of a semiconductor wafer W is supported on top surfaces of the two support main body pieces 104A. That is, the semiconductor wafer W is supported across on the top surfaces of the two support main body pieces 104A, the two support main body pieces 104A extending over the semiconductor wafer W. The two support main body pieces 104A are configured to be moved up and down at the same time by two elevating rods that are driven synchronously. The two elevating rods 80 may be connected so as to be moved up and down by a single actuator.

A multiple number of, e.g., two supporting body units 114 in this example are provided on a top surface of each support main body piece 104A, and a rear surface of the semiconductor wafer W is supported by a supporting body 108 of each supporting body unit 114. Any of the supporting body units described in FIGS. 1 to 16B may be used as the supporting body unit 114. Accordingly, formation of a scratch, a flaw, or the like on the rear surface of the semiconductor wafer W can be still prevented as in the cases described above.

(Application to a Processing Apparatus)

In each of the embodiment and modifications described in FIGS. 1 to 16B, the support structure has been described to be applied to a single-wafer type load lock apparatus that transfers semiconductor wafers W one by one. However, the present embodiment may not be limited thereto. For example, the support structure may be applied to the processing apparatuses 14A to 14D. In such a case, the above-described support structure may be used as each of the mounting tables 22A to 22D. Further, a heating unit 44 as a heat source 110 may be provided in a support main body 104 when necessary. Even in the above-described configuration, formation of a scratch, a flaw, or the like on a rear surface of a semiconductor wafer W can be prevented when the semiconductor wafer contracts due to the cooling thereof.

(Application to a Transfer Mechanism)

In each of the embodiment and modifications described in FIGS. 1 to 16B, the support structure has been described to be applied to a single-wafer type load lock apparatus that transfers semiconductor wafers W one by one. However, the present embodiment may not be limited thereto. For example, the support structure may be applied to the transfer mechanisms 24 and 34.

FIG. 20 presents a schematic plane view illustrating an example in which the support structure in accordance with the present embodiment is applied to the first transfer mechanism 24 provided in the transfer chamber 16 (see FIG. 1). In this case, the support structure may be applied to each of the two picks 25A and 25B fixed at the leading ends of the arm member 25. That is, a support main body 104 is formed in a thin forked pick shape, and aforementioned supporting body unit 114 having supporting bodies 108 are provided on the surface of the support main body 104.

Here, a total of three supporting body units 114 are provided: one at a base portion of the pick and two at both leading ends thereof. A semiconductor wafer W is supported by these three supporting body units 114. The number of the supporting body units 114, however, may not be limited to this example, and a greater number of supporting body units 114 may be provided.

Further, although the first transfer mechanism 24 is illustrated in this example, the support structure in accordance with the present embodiment may also be applied to the second transfer mechanism 34. With this configuration, formation of a scratch, a flaw, or the like on the rear surface wafer W can be prevented regardless whether the semiconductor is thermally expanded or contracted.

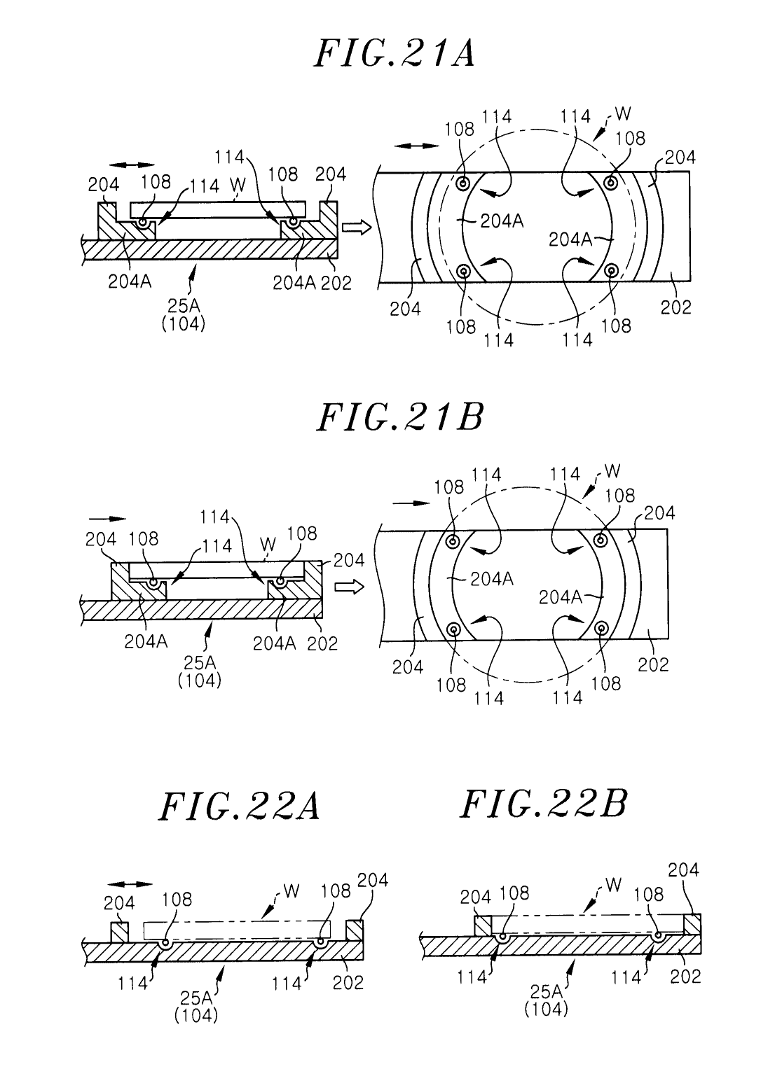

Furthermore, in the above description, although the picks having the forked shapes are used as the picks 25A and 25B, the present embodiment may not be limited thereto and may be applied to a pick of any shape. For example, FIGS. 21A and 21B illustrate a first modification example of the pick shape, and a cross sectional view and a plane view are provided together in each figure. A pick 25A (104) serving as a support main body 104 has a base plate 202, and a pair of circular arc-shaped substrate holding components 204 are provided on the base plate 202. The substrate holding components 204 are spaced apart from each other at a distance equal to or greater than a diameter of a semiconductor wafer W. Further, the substrate holding components 204 are supported on the base plate 202 such that they can approach each other or move away from each other.

In FIG. 21A, one (left one) of the substrate holding components 204 is configured to be slidable in a length direction of the base plate 202. The substrate holding components 204 are formed to have L-shaped cross sections so as to form stepped portions 204A, respectively, and the stepped portions 204A are provided to face each other. A peripheral rear surface of the semiconductor wafer W comes into contact with the stepped portions 204A to thereby be supported thereon.

Aforementioned supporting body units 114 including supporting bodies 108 and the like are provided on surfaces of the stepped portions 204A at both ends thereof. That is, a total of four supporting body units 114 are provided in FIGS. 21A and 21B. However, the number of the supporting body units 114 may not be limited thereto. FIG. 21A shows a state before the semiconductor wafer W is held by the substrate holding components 204, whereas FIG. 21B shows a state in which the semiconductor wafer W is held by substrate holding components 204.

In case of a conventional pick without applying the supporting body units 104 thereto, friction may be generated between the rear surface of the semiconductor wafer W and the surfaces of the stepped portions 204A of the support holding components 204 when the substrate holding components 204 move to hold the semiconductor wafer W, resulting in formation of a scratch, a flaw, or the like on the rear surface of the semiconductor wafer W. As stated above, however, by providing the supporting body units 114, the supporting bodies 108 of the supporting body units 114 may roll or rock when the left substrate holding component 204 moves to hold the semiconductor wafer W between the substrate holding components 204, so that formation of a scratch, a flaw, or the like on the rear surface of the semiconductor wafer W can be prevented.

FIGS. 22A and 22B illustrate a second modification example of the pick shape. FIG. 22A shows a state before a semiconductor wafer W is held by substrate holding components, whereas FIG. 22B shows a state in which the semiconductor wafer is held by substrate holding components. Here, a pair of substrate holding components does not have stepped portions 204A, and they are formed as circular arc-shaped frames. Aforementioned supporting body units 114 having supporting bodies 108 and the like are directly provided on the top surface of a base plate 202 between the pair of substrate holding components 204. In the example shown in FIGS. 22A and 22B, one (left one) of the two substrate holding components 204 is configured to be slidable in the length direction of the base plate 202.

The pick in accordance with the second modification example may achieve the similar effect as that obtained by the pick in accordance with the first modification example. Furthermore, in FIGS. 21A to 22B, the other one (right one) of the two substrate holding components 204 may be configured to be slidable, or both of the two substrate holding components 204 may be configured to be slidable so as to approach or move away from each other. Moreover, in FIGS. 21A to 22B, the other pick 25B has the same configuration as that of the pick 25A. In addition, any of the supporting body units described in the aforementioned embodiment and modifications may be used as the supporting body unit 114.

(Application to a Load Lock Apparatus Capable of Accommodating a Multiple Number of Substrates)

In each of the embodiment and modifications described in FIGS. 1 to 16B, the support structure has been described to be applied to a single-wafer type load lock apparatus that transfers semiconductor wafers W one by one. However, the present embodiment may not be limited thereto. For example, the support structure may be applied to a load lock apparatus capable of cooling a multiple number of semiconductor wafers at a time. Such a lock apparatus may have advantages when a processing apparatus capable of processing a multiple number of semiconductor wafers at a time is used.

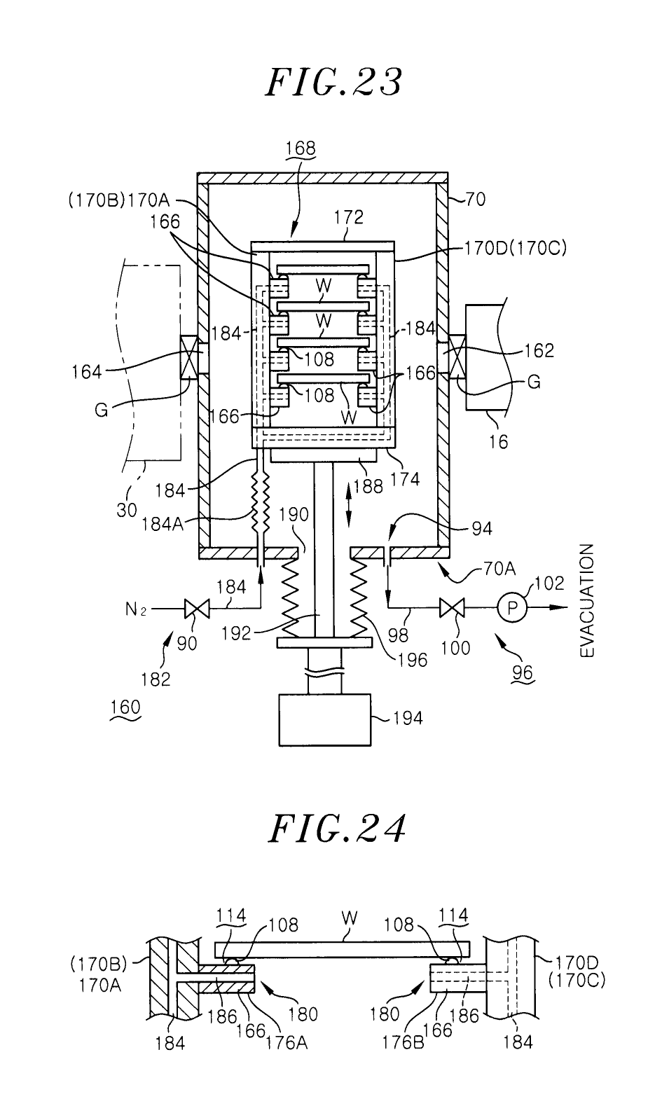

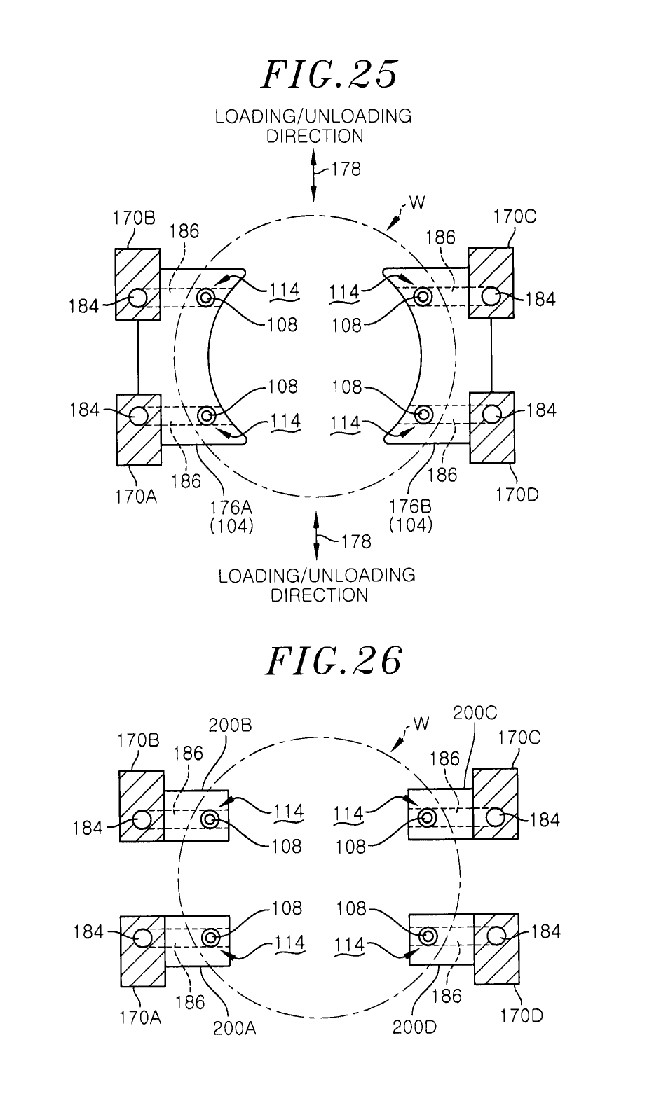

FIG. 23 provides a longitudinal cross sectional view illustrating a load lock apparatus capable of accommodating a multiple number of semiconductor wafers to which the support structure in accordance with the present embodiment is applied. FIG. 24 is an enlarged partial cross sectional view illustrating a part of a supporting unit that supports processing target objects, and FIG. 25 is a plane view illustrating an example of a supporting member of the supporting unit. Further, like reference numerals will be given to like parts described in FIGS. 1 to 16B, and redundant description thereof will be omitted.

As shown in the FIG. 23, a load lock apparatus 160 includes a vertically elongated load lock chamber 70. The load lock chamber 70 is made of a metal such as an aluminum alloy or stainless steel in a box shape. A vacuum side loading/unloading port 162 through which a semiconductor wafer W is loaded or unloaded is provided in an intermediate portion at one side of the load lock chamber 70, and the transfer chamber 16 is connected to the vacuum side loading/unloading port 162 via a gate valve G. Further, an atmospheric side loading/unloading port 164 through which a semiconductor wafer W is loaded or unloaded is provided in an intermediate portion at the other side of the load lock chamber 70 to oppositely face the vacuum side loading/unloading port 162. The loading module 30 is connected to the atmospheric side loading/unloading port 164 via a gate valve G.

A gas exhaust port 94 is provided at a bottom 70A of the load lock chamber 70, and a gas exhaust unit 96 for evacuating an internal atmosphere of the load lock chamber 70 to a vacuum level is connected to the gas exhaust port 94. To elaborate, the gas exhaust unit 96 has a gas passage 98 connected with the gas exhaust port 94, and an opening/closing valve 100 and a vacuum pump 102 are sequentially installed on the gas passage 98.

Provided in the load lock chamber 70 is a supporting unit 168 including supporting members 166 configured to support a multiple number of semiconductor wafers W as processing target objects in multi levels. The above-described support structure may be applied to the supporting members 166. As shown in FIG. 25, the supporting unit 168 includes a plurality of, e.g., four supporting posts 170A, 170B, 170C and 170D arranged in a rectangular shape. Upper ends of the four supporting posts 170A to 170D are mounted to a ceiling plate 172 as one body, while their lower ends are mounted to a bottom plate 174 as one body. The supporting posts 170A to 170D are divided into two groups: a group of 170A and 170B and a group of 170C and 170D. A distance between the two groups is set to be slightly greater than a diameter of a semiconductor wafer W so as to allow the semiconductor wafer W to be inserted between the two groups of supporting posts 70A to 70D.

The supporting members 166 to which the support structure in accordance with the present embodiment is applied are fixed to the supporting posts 170A to 170D in multi levels, e.g., in four levels in this example, at a preset pitch in a longitudinal direction of the supporting posts 170A to 170D. Four semiconductor wafers W can be held on the supporting members 166. Here, each of the supporting members 166 includes a pair of shelf members 176A and 176B arranged to face each other. One shelf member 176A is horizontally fixed to be laid across over the two supporting posts 170A and 170B at one side, while the other shelf member 176B is horizontally fixed to be laid across over the two supporting posts 170C and 170D at the other side. Here, the pair of shelf members 176A and 176B forms the support main body 104 of the support structure in accordance with the present embodiment.

Facing portions of the shelf members 176A and 176B are formed in circular arc shapes conforming to the circumference of the semiconductor wafer W. The semiconductor wafer W is mounted on top surfaces of the shelf members 176A and 176B and thus is supported thereon. To be more specific, the aforementioned supporting body units 114, each of which has a supporting body 108 and the like, are provided at both ends of the facing portion of each of the shelf members 176A and 176B forming the support main body 104. That is, a total of four supporting body units 114 are provided. A rear surface of the semiconductor wafer W comes into contact with upper ends of the supporting bodies 108 of the four supporting body units 114 and thus is supported thereon.

Here, the number of the supporting body units 114 is not limited to four but may be increased. The preset pitch in a height direction between the supporting members 166 may be set to range from, e.g., about 10 mm to about 30 mm so as to allow the approach of the picks 25A and 25B and the picks 35A and 35B of the transfer mechanism 24 and 34 holding semiconductor wafers W thereon.

In this configuration, the picks 25A, 25B, 35A and 35B may enter a space between the one set of supporting posts 170A and 170B and the other set of supporting posts 170C and 170D, and a direction indicated by an arrow 178 becomes a loading/unloading direction. Here, the supporting unit 168 may be made of one or more materials selected from a group consisting of a ceramic material, quartz, a metal and a heat resistant resin. Preferably, the supporting posts 170A to 170D, the ceiling plate 172 and the bottom plate 174 may be made of a metal such as an aluminum alloy, whereas the supporting members 166 that support the weight of the semiconductor wafers W may be made of a heat resistant member such as quartz or a ceramic material.

The supporting unit 168 includes a gas introduction unit 182 having gas injection openings 180 provided to correspond to the supporting members 166 so as to introduce an atmospheric pressure restoring gas as a cooling gas. To elaborate, the gas introduction unit 182 has gas inlet passages 184 formed in the supporting unit 168. Here, a gas inlet passage 184 is formed in each of the four supporting posts 170A to 170D in their longitudinal direction, and gas nozzles 186 are horizontally formed to pass through the inside of the shelf members 176A and 176B of the supporting members 166 from the respective gas inlet passages 184.

Accordingly, leading ends of the gas nozzles 186 are configured as gas injection openings 180. With this configuration, the cooling gas can be introduced in a horizontal direction, corresponding to each supporting member 166. In this example, a single semiconductor wafer W may be cooled by the cooling gas introduced from the four gas injection openings 180. Further, the number of the gas injection openings 180 for the single semiconductor wafer W may not be limited to four but can be increased or decreased as required.

Further, the four gas inlet passages 184 pass through the bottom plate 174, and the four gas inlet passages 184 are taken out of the load lock chamber 70 airtightly through the bottom 70A of the load lock chamber 70 after merged as a single passage. Moreover, an expansible and contractible bellows 184A is provided at a part of the merged single gas inlet passage 184 located in the load lock chamber 70, and the bellows 184A may be expanded or contracted in accordance with the elevation of the supporting unit 168.

Further, an opening/closing valve 90 is provided in a part of the merged single gas inlet passage 184 to allow a supply of the atmospheric pressure restoring gas as the cooling gas when necessary. A rare gas such as a He gas or an Ar gas, or an inert gas such as a N₂ gas may be used as the atmospheric pressure restoring gas (cooling gas). In this example, the N₂ gas is used. Here, if the temperature of the cooling gas is excessively low, a semiconductor wafer in a high temperature state may be suddenly cooled and suffer damage. Thus, the temperature of the cooling gas needs to be set depending on the temperature of the semiconductor wafer to be cooled. For example, the temperature of the cooling gas may be set to be a room temperature.

The bottom plate 174 of the supporting unit 168 having the above-described configuration is installed on an elevation table 188, and, thus, the supporting unit 168 is movable up and down. To be more specific, the elevation table 188 is fixed to an upper end of an elevating rod 192 inserted through a through hole 190 provided in the bottom 70A of the load lock chamber 70. An actuator 194 connected to a lower end of the elevating rod 192 is configured to move the elevating rod 192 up and down.

In this case, the actuator 194 moves the elevating table 188 up and down to allow the supporting members 166 at certain positions in a vertical direction to be stopped in multi levels to correspond to a horizontal level of the pick of the transfer mechanism. Further, an expansible/contractible metallic bellows 196 is fixed to the bottom 70A to surround the through hole 190 of the elevating rod 192, so that the elevating rod 192 can be moved up and down while maintaining airtightness of the inside of the load lock chamber 70.

The load lock apparatus 160 having the above-described configuration may be operated as follows. To transfer a semiconductor wafer w onto a supporting member 166 of the supporting unit 168 held on a pick, the pick holding the semiconductor wafer W is inserted into a space above the corresponding supporting member 166. Then, by driving the actuator 194, the entire supporting unit 168 is raised by a preset distance, whereby the semiconductor wafer W held on the pick is mounted on the supporting member 166. Then, by taking out the pick, the transfer of the semiconductor wafer W is completed.

On the other hand, to transfer a semiconductor wafer W held on the supporting member 166 onto a pick, an empty pick is inserted into a space under the supporting member 166 holding the semiconductor wafer W. Then, by driving the actuator 194, the supporting unit 168 is lowered by a preset distance, whereby the semiconductor wafer W is placed on the pick. Thereafter, by taking out the pick on which the semiconductor wafer W is supported, the transfer of the semiconductor wafer W is completed.

To elaborate, by using the first transfer mechanism 24 of the transfer chamber 16, processed high-temperature semiconductor wafers W are supported in multi levels on the supporting members 166 of the supporting unit 168 in the load lock chamber 70 whose inside is previously turned into a vacuum state. At this time, rear surfaces of the semiconductor wafers W come into contact with the supporting bodies 108 of the support structures forming the supporting members 166, and, thus, the semiconductor wafers W are supported on the supporting bodies 108.

Then, by closing the gate valve G on the side of the transfer chamber 16, the inside of the load lock chamber 70 is airtightly sealed. Then, by opening the opening/closing valve 90 of the gas introduction unit 182, a N₂ gas used as an atmospheric pressure restoring gas and as a cooling gas is introduced at a predetermined flow rate. The introduced N₂ gas flows in the respective gas inlet passages 184 provided in the supporting posts 170A to 170D of the supporting unit 168, and, then, the N₂ gas is introduced onto the rear surfaces of the semiconductor wafers W through the gas injection openings 180 at the leading ends of the nozzles 186 communicating with the gas inlet passages 184.

Since the gas injection openings 180 are provided to correspond to the respective supporting members 166, the four semiconductor wafers W held on the respective supporting members 166 may be cooled approximately at the same time by the introduced N₂ gas. Here, since every single semiconductor wafer W is cooled by the N₂ gas introduced from the four gas injection openings 180, the semiconductor wafer W can be cooled efficiently.

In this case, since the semiconductor wafers W are in contact with the supporting bodies 108 and supported on the supporting bodies 108 of the support structures forming the supporting members 166, formation of a scratch, a flaw, or the like on the rear surfaces of the semiconductor wafers W can be prevented even if the semiconductor wafers W thermally expand or contract.

Furthermore, in the embodiment shown in FIGS. 23 to 25, although the shelf members 176A and 176B are placed between the two supporting posts 170A and 170B and between the two supporting posts 170C and 170D, respectively, as supporting members 166 that support a semiconductor wafer W, the present embodiment may not be limited to this configuration. For example, blocks may be individually provided at the respective supporting posts 170A to 170D. FIG. 26 is an enlarged view illustrating a cross section of a supporting unit of a load lock apparatus in accordance with a modification of the embodiment. In FIG. 26, the same parts as those described in FIGS. 23 to 26 will be assigned same reference numerals, and redundant description thereof will be omitted.

As mentioned above, blocks 200A, 200B, 200C and 200D are horizontally fixed to supporting posts 170A to 170D of a supporting unit 168, respectively, as supporting members 166. The four blocks 200A to 200D may form a single support main body 104, and a supporting body unit 114 having a supporting body 108 and the like is provided on each of the blocks 200A to 200D.

A semiconductor wafer W comes into contact with the supporting bodies 108 provided on the blocks 200A to 200D and is supported thereon. Here, the blocks 200A to 200D may be made of the same material as used to form the shelf members 176A and 176B. Further, a nozzle 186 and a gas injection opening 180 having the same configurations as those described in FIG. 25 and configured to communicate with gas inlet passages 184 are formed in each of the blocks 200A to 200D so as to introduce an inert gas, e.g., a N₂ gas, serving as both an atmospheric pressure restoring gas and a cooling gas. In this modification, the similar effects as obtained in the aforementioned embodiment and modifications can be still achieved.

(Application to a Lifter Mechanism of a Support Structure)

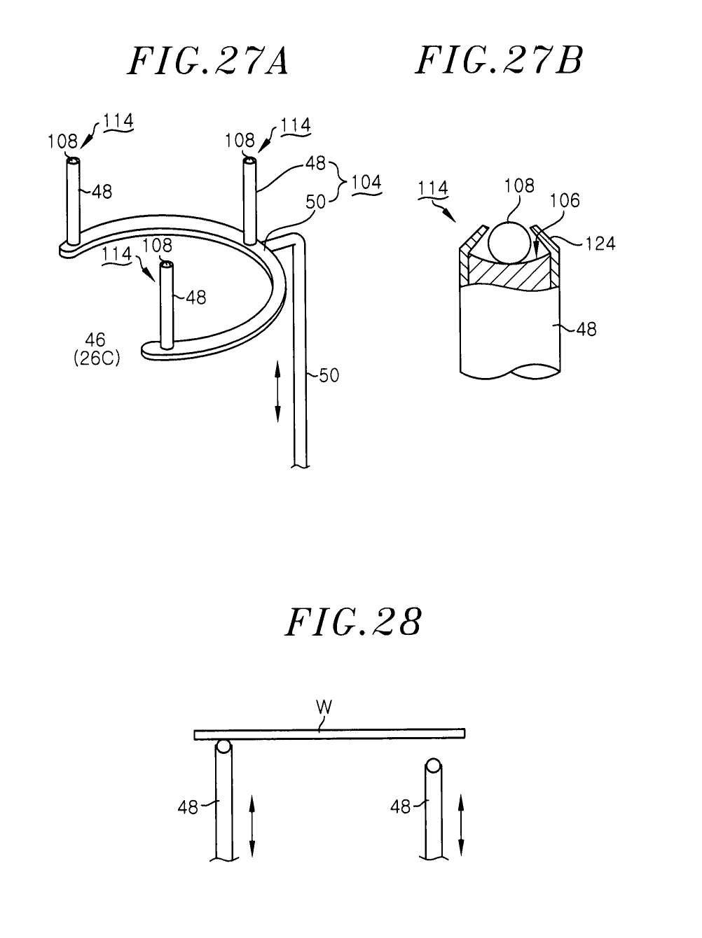

Now, an example of applying the support structures in accordance with the aforementioned embodiment and modifications to a lifter mechanism will be described. The support structure in accordance with the present embodiment may be applied to the lifter mechanism 74 of the load lock apparatus 20A (20B) or the lifter mechanism 46 of the processing apparatus 14A (14B to 14D). FIGS. 27A and 27B illustrate an example lifter mechanism to which the support structure in accordance with the present embodiment is applied. FIG. 28 is a view for describing an operation of the lifter mechanism shown in FIGS. 27A and 27B. FIG. 27A is a perspective view of the lifter mechanism, and FIG. 27B is an enlarged cross sectional view of an elevating pin of the lifter mechanism.

In general, in a lifter mechanism, a semiconductor wafer may be moved up and down with its rear surface supported by three elevating pins. However, the lifter mechanism may be bent due to a weight of the semiconductor wafer, and upper ends of the elevating pins may not be located on a same horizontal level, resulting in a height difference in a vertical direction. In such a case, when a semiconductor wafer is transferred onto a mounting table 22A for mounting the semiconductor wafer W thereon or onto a support main body 10 (see FIG. 2), timings at which the upper ends of the three elevating pins come into contact with the rear surface of the semiconductor wafer may become slightly different. As a result, the semiconductor wafer may be temporarily inclined, and the upper ends of the elevating pins may be slipped off the rear surface of the semiconductor wafer W, which in turn may cause generation of particles or the like as mentioned above.

Therefore, the support structure as described above is applied to the lifter mechanism in accordance with the present embodiment. Although the support structure may be applied to lifter mechanisms of all of the processing apparatuses, an example of applying the support structure in accordance with the present embodiment to the lifter mechanism 46 of the processing apparatus 14A will be explained here. As depicted in FIGS. 27A and 27B, the lifter mechanism 46 (see FIG. 2) includes the three elevating pins 48 provided on the top surface of the elevating plate 50 formed in the circular arc shape, and this entire structure is moved up and down by the elevating rod 51 connected with the actuator. In case that a support structure 26C in accordance with a modification is applied to the lifter mechanism 46, the elevating plate 50 and the three elevating pins provided on the top surface of the elevating plate 50 may form a support main body 104 and support a weight of a semiconductor wafer W.

Further, as shown in FIG. 27B, a supporting body unit 114 having a supporting body accommodating portion 106, a sphere-shaped supporting body 108 and a jump-out preventing cover member 124 is provided at an upper end of each elevating pin 48. The supporting body unit 114 may be similar to the supporting body unit described in FIG. 10.

With the above configuration, when a semiconductor wafer W is transferred onto, e.g., the mounting table 22A (see FIG. 2) by operating the support structure 26C applied to the lifter mechanism 46, the elevating plate 50 or the like may be bent due to a weight of the semiconductor wafer W or the like, and upper ends of the elevating pins 48 may not be located on a same horizontal level and the upper ends of the elevating pins 48 may be slipped off the rear surface of the semiconductor wafer W, as illustrated in FIG. 28.

In this example however, since the supporting body unit 114 is provided at the upper end of each supporting pin 48, the spherical supporting body 108 of the supporting body unit 114 may rotate or roll, and, thus, such slipping can be prevented. In this case, the supporting body 108 rolls just several micrometers (μm), but formation of a scratch, a flaw, or the like on the rear surface of the semiconductor wafer W can be still prevented.

(Application of a Support Structure to a Mounting Table of a Semi-Batch Type Processing Apparatus)

Now, an example of applying the support structure in accordance with the present embodiment to a mounting table within a processing apparatus will be explained. Here, a semi-batch type processing apparatus that processes about two to ten semiconductor wafers at a time, not a single-wafer type processing apparatus that processes semiconductor wafers one by one, may be used.

A basic structure of this semi-batch type processing apparatus may be substantially the same as that of the processing apparatus 14A illustrated in FIG. 2. That is, the semi-batch type processing apparatus further includes a gas supply unit 58, a gas exhaust unit 62, a lifter mechanism 46 and a heating unit 44. However, this semi-batch type processing apparatus is different from the processing apparatus 14A in FIG. 2 in that it has a mounting table having a size capable of mounting thereon a multiple number of semiconductor wafers thereon, not a mounting table 22A having a size suitable for mounting a single semiconductor wafer W thereon. A process is performed on the semiconductor wafers in this semi-batch type processing apparatus while the mounting table is rotated.

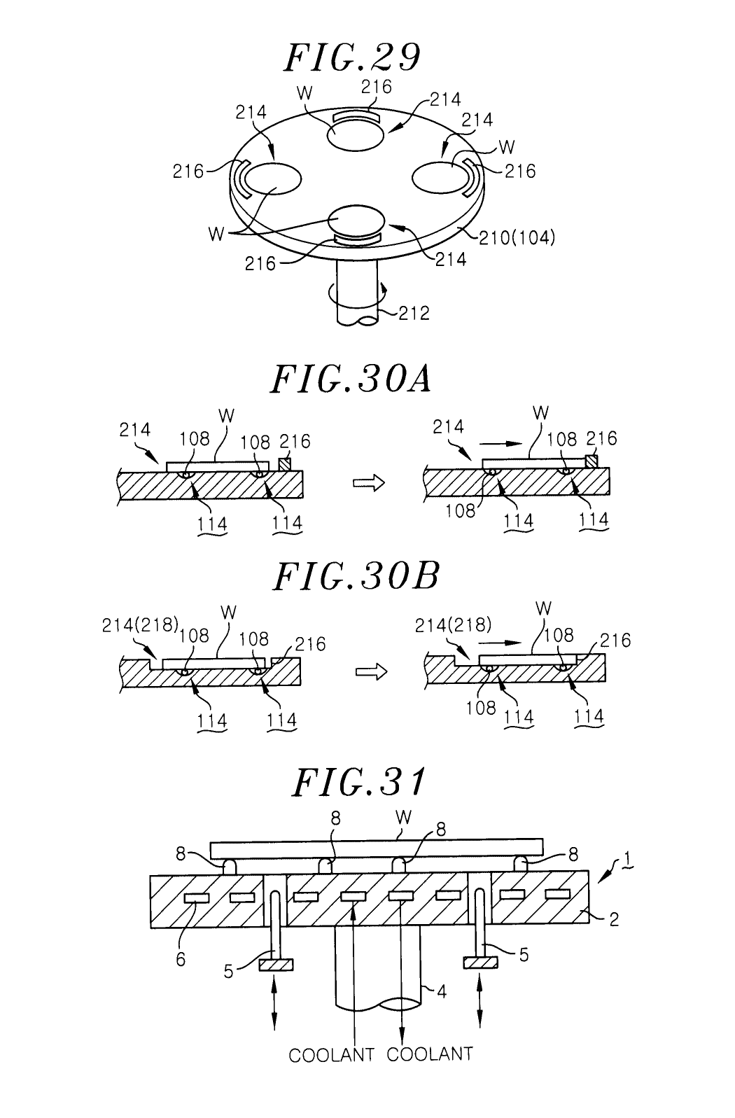

FIG. 29 is a perspective view illustrating the mounting table of the semi-batch type processing apparatus to which a support structure in accordance with a modification of the embodiment is applied. FIG. 30 presents a partial enlarged cross sectional view showing a part of the mounting table of the processing apparatus shown in FIG. 29. As depicted in the figures, a mounting table 210 of the semi-batch type processing apparatus is formed in a circular plate shape having a size capable of mounting a multiple number of, e.g., four semiconductor wafers W thereon. The mounting table 210 can be rotated at a preset rotational speed by a rotation shaft 212 connected to a non-illustrated rotating motor. Mounting spaces 214 are prepared on the top surface of the mounting table 210 at a same interval along the circumference of the mounting table 210, and the semiconductor wafers W are respectively mounted on the mounting spaces 214.

Further, as shown in FIG. 30A, a semiconductor wafer stopper 216 for preventing the semiconductor wafer W from being projected outward by a centrifugal force is provided outside each mounting space 214 along an outer circumference thereof. Here, as illustrated in FIG. 30B, the mounting space 214 may be formed as a recess larger than the semiconductor wafer W, and a stepped portion of the recess 218 may be configured as a semiconductor wafer stopper 216.

When a support structure 26D in accordance with a modification is applied to the mounting table 210 configured as described above, the mounting table 210 may serve as a support main body 104. Supporting body units 114 may be provided on the top surface of each mounting space 214 of the mounting table 210 configured as the support main body 104, as illustrated in FIGS. 30A and 30B, and a semiconductor wafer W is mounted on the supporting body units 114. Here, as in the case described earlier, a total of nine supporting body units 114 may be provided on the top surface of each mounting space 214, for example. Any of the supporting body units as described in FIGS. 3 to 13B may be used as the supporting body unit 114 in this example. For example, the supporting body unit 114 may be configured to include a supporting body accommodating portion 106 and a supporting body 108, or it may be configured to further include a jump-out preventing cover member 124 in addition to the supporting body accommodating portion 106 and the supporting body 108.

In the above-described configuration, when the mounting table 210 is rotated, the semiconductor wafer W mounted on each mounting space 214 may be slightly slid sideways in a radially outward direction by a centrifugal force, and this semiconductor wafer W may be stopped by the semiconductor wafer stopper 216.

When the semiconductor wafer W is slid sideways, slipping of the bottom surface of the semiconductor wafer or formation of a flaw or the like on the bottom surface of the semiconductor wafer W may occur in a conventional mounting table, as mentioned earlier. In accordance with the embodiments of the present invention, however, since the supporting body unit 114 is provided and the spherical supporting body 108 of the supporting body unit 114 is rotated, the slipping can be prevented. In this case, formation of a scratch, a flaw, or the like on the rear surface of the semiconductor wafer W can also be suppressed.

Further, in the above-described embodiments, although the semiconductor wafer is described as a processing target object, the processing target object may not be limited thereto, and the present invention is also applicable to a glass substrate, a LCD substrate, a ceramic substrate, and the like.

While the invention has been shown and described with respect to the embodiments, it will be understood by those skilled in the art that various changes and modification may be made without departing from the scope of the invention as defined in the following claims.

What is claimed is:

1. A support structure for supporting a processing target object, comprising:
a support main body that supports a weight of the processing target object;
recess-shaped supporting body accommodating portions formed on a top surface of the support main body; and
supporting bodies accommodated in the respective supporting body accommodating portions to be protruded above the top surface of the support main body, the supporting bodies being rollable in the respective supporting body accommodating portions while supporting the processing target object of which bottom surface is in contact with upper peak portions of the supporting bodies.

2. The support structure of claim 1, wherein each of the supporting bodies is formed in a sphere shape.

3. The support structure of claim 2, wherein a bottom surface of each of the supporting body accommodating portions is formed in a curved surface shape to allow the corresponding supporting body therein to return to an original position thereof when the processing target object is separated from the supporting body.

4. The supporting structure of claim 3, wherein the curved surface shape is a round shape in section, a conical shape or an elliptical arc shape in section.

5. The support structure of claim 3, wherein the curved surface shape is formed such that a central portion thereof is lowest.

6. The support structure of claim 5, wherein a particle deposit surface is horizontally formed around the bottom surface of each of the supporting body accommodating portions to make particles entering the supporting body accommodating portion be accumulated therein.

7. The support structure of claim 1, wherein a bottom surface of each of the supporting body accommodating portions is inclined with respect to a thermal expansion/contraction direction of the processing target object to allow the corresponding supporting body therein to return to an original position thereof when the processing target object is separated from the supporting body.

8. The support structure of claim 1, wherein each of the supporting bodies is formed in a cylinder shape.

9. The support structure of claim 8, wherein a bottom surface of each of the supporting body accommodating portions is inclined with respect to a thermal expansion/contraction direction of the processing target object to allow the corresponding supporting body therein to return to an original position thereof when the processing target object is separated from the supporting body.

10. A support structure for supporting a processing target object, comprising:
a support main body that supports a weight of the processing target object;
recess-shaped supporting body accommodating portions formed on a top surface of the support main body; and
supporting bodies accommodated in the respective supporting body accommodating portions to be protruded above the top surface of the support main body, the supporting bodies being rockable in the supporting body accommodating portions while supporting the processing target object of which bottom surface is in contact with upper peak portions of the supporting bodies.

11. The support structure of claim 10, wherein a bottom surface of each of the supporting body accommodating portions is formed as a plane surface and has a shape to allow the corresponding supporting body to return to an original position thereof by its own gravity when the processing target object is separated from the supporting body.

12. The support structure of claim 11, wherein the shape of the bottom surface of each of the supporting body accommodating portions is an elliptical arc shape in section.

13. The support structure of claim 1, wherein a jump-out preventing cover member is provided above each of the supporting body accommodating portions to prevent the corresponding supporting body from moving out of the supporting body accommodating portion.

14. A support structure for supporting a processing target object, comprising:
a support main body that supports a weight of the processing target object;
recess-shaped supporting body accommodating portions formed on a top surface of the support main body; and
supporting bodies accommodated in the respective supporting body accommodating portions to be protruded above the top surface of the support main body, the supporting bodies being rotatably supported in the supporting body accommodating portions while supporting the processing target object of which bottom surface is in contact with upper peak portions of the supporting bodies.

15. The support structure of claim 14, wherein each of the supporting bodies is supported in a direction perpendicular to a thermal expansion/contraction direction of the processing target object.

16. The support structure of claim 1, wherein the support main body includes:
an elevating plate configured to be moved up and down by an actuator; and
elevating pins provided on a top surface of the elevating plate,
wherein each of the supporting body accommodating portions is formed at an upper end of each of the elevating pins.

17. The support structure of claim 1, wherein the support main body is rotatable and is configured to be capable of mounting thereon a multiple number of processing target objects at the same time.

18. A load lock apparatus connected between a vacuum chamber and an atmospheric chamber via gate valves and capable of selectively creating therein a vacuum atmosphere and an atmospheric atmosphere, the apparatus comprising:
a load lock chamber capable of being evacuated to a vacuum level and returned back into an atmospheric pressure;
the support structure of claim 1 provided in the load lock chamber;
a heat source for heating and/or cooling the processing target object;
a lifter mechanism that places the processing target object on the support main body and moves the processing target object away from the support main body; and
a gas exhaust unit that evacuates an internal atmosphere of the load lock chamber to vacuum.

19. A load lock apparatus connected between a vacuum chamber and an atmospheric chamber via gate valves and capable of selectively creating therein a vacuum atmosphere and an atmospheric atmosphere, the apparatus comprising:
a load lock chamber;
the supporting structure of claim 1 provided in a plural number;
a supporting unit having the supporting structures provided in the load lock chamber to support a multiple number of processing target objects in multiple levels;
a gas introduction unit having gas injection openings provided to correspond to the support structures to introduce an atmospheric pressure restoring gas as a cooling gas; and
a gas exhaust unit that evacuates an internal atmosphere of the load lock chamber to a vacuum level.

20. The load lock apparatus of claim 19, wherein the supporting unit includes uprightly standing supporting posts, and the support structures are fixed to the supporting posts at a preset pitch.

21. The load lock apparatus of claim 19, wherein the gas introduction unit has a gas inlet passage formed in the supporting unit.

22. The load lock apparatus of claim 19, wherein the supporting unit is installed on an elevating plate that is movable up and down.

23. A processing apparatus for performing a preset process on a processing target object, comprising:
a processing chamber that accommodates the processing target object therein;
the support structure of claim 1 provided within the processing chamber;
a heating unit that heats the processing target object;
a lifter mechanism that places the processing target object on the support main body and moves the processing target object away from the support main body;
a gas supply unit that supplies a processing gas into the processing chamber; and
a gas exhaust unit that evacuates an internal atmosphere of the processing chamber to a vacuum level.

24. The load lock apparatus of claim 18, wherein the lifter mechanism is made up of the supporting structure of claim 16.

25. The load lock apparatus of claim 23, wherein the lifter mechanism is made up of the supporting structure of claim 16.

26. A transfer mechanism for transferring a processing target object, comprising:
an arm member configured to be capable of making an extending/retracting motion and a rotating motion; and
the support structure of claim 1 provided on a leading end of the arm member.

27. The transfer mechanism of claim 26, wherein the arm member includes a holding component that holds a circumferential periphery of the processing target object, and the holding component is moved to hold the processing target object.
